(19) United States
(12) Patent Application Publication
(10) Pub. No.: US 2004/0217411 A1
(43) Pub. Date: Nov. 4, 2004

(54) Non-volatile semiconductor memory device and manufacturing method therefor

(75) Inventors: Jun Ohtani, Hyogo (JP); Tsukasa Ooishi, Hyogo (JP)

Correspondence Address: McDermott, Will & Emery, 600 13th Street, N.W., Washington, DC, 20005-3096, US

(73) Assignee: RENESAS TECHNOLOGY CORP., Tokyo (JP)

(21) Appl. No.: 10/859,122

(22) Filed: Jun. 3, 2004

Related U.S. Application Data
(62) Division of application No. 10/224,319, filed on Aug. 21, 2002.

(30) Foreign Application Priority Data
Feb. 20, 2002 (JP) 2002-043600(P)

(51) Int. Cl. H01L 29/76

(52) U.S. Cl. 257/314

(57) ABSTRACT

A non-volatile semiconductor memory device of the present invention is provided with a semiconductor substrate having a main surface, an ONO film (a laminated film of an oxide film, a nitride film and an oxide film) formed on the main surface and having a charge storage part, a pair of buried diffusion bit lines formed in the semiconductor substrate located on both sides of the ONO film, oxide films deposited on the main surface so as to cover the buried diffusion bit lines, and a transfer gate electrode formed on the ONO film.

### BACKGROUND OF THE INVENTION

1. Field of the Invention

The present invention relates to a non-volatile semiconductor memory device and a manufacturing method for the same, and more particularly to a non-volatile semiconductor memory device (NROM: Nitrided Read Only Memory) provided with a memory cell having a laminated film of an oxide film, a nitride film and an oxide film (hereinafter referred to as “ONO film” and a manufacturing method for the same.

2. Description of the Background Art

A semiconductor device wherein a transistor having an ONO film is used as a non-volatile memory cell is described in, for example, U.S. Pat. No. 6,174,758. The semiconductor device described in this reference has a memory cell 2 in a semiconductor substrate 1 as shown in FIG. 65. Memory cell 2 is provided with a pair of buried diffusion bit lines 3 that become the source/drain, bit line oxidized regions 5 formed on buried diffusion bit lines 3, respectively, an ONO film 9 formed between bit line oxidized regions 5, a doped polysilicon film 7 and a metal silicide film 8.

ONO film 9 has a floating gate structure and the silicon nitride film in ONO film 9 becomes a floating gate layer. In addition, doped polysilicon film 7 and metal silicide film 8 form a polycide control gate.

Next, write-in, read-out and erasing operations of a semiconductor device of the type described above are briefly described.

Write-in is carried out by injecting channel hot electrons into the silicon nitride film in ONO film 9. Concretely, 9V, for example, is applied to the polycide gate, the potential of the source (buried diffusion bit line 3) is set at 0V and 4.5V is applied to the drain (buried diffusion bit line 4). Thereby, electrons flow from the source toward the drain and the electrons that have become channel hot electrons in the vicinity of the drain are injected into the silicon nitride film in ONO film 9. The electrons injected into the silicon nitride film do not move in the lateral direction in FIG. 65. Therefore, 2-bits can be written into one cell by inverting the source/drain.

At the time of read-out, the source and the drain are inverted from the condition at the time of write-in. When the bit line potential is set at a predetermined potential, the drain side becomes of a punch-through condition so that information of electrons is not detected and only the existence of electrons on the source side can be detected. Information on the drain side is read-out by again inverting the source and drain.

At the time of the erasing operation, tunneling between bands wherein holes are accelerated in the lateral direction so as to be injected into the silicon nitride film is used, and thereby bit unit erasure is carried out. For example, −5V is applied to the polycide gate, the source is set at an open condition and 5V is applied to the drain. Thereby, holes flow from the drain toward the polycide gate so as to be injected into the silicon nitride film.

In order to gain the structure shown in FIG. 65, ONO film 9 is formed over the entirety of semiconductor substrate 1 and a plurality of buried diffusion bit lines 3 are formed by selectively implanting n-type impurities into semiconductor substrate 1 and, after that, thermal oxidation is carried out so as to form bit line oxidized regions 5 on buried diffusion bit lines 3 and doped polysilicon film 7 and metal silicide film 8 are formed on the oxidized regions.

As shown in FIG. 65, the end portions of bit line oxidized regions 5 extend to below ONO film 9 in a form such as a bird's beak so that the end portions of ONO film 9 pushed upward by bit line oxidized regions 5. Portions pushed upward in such a manner are the portions that do not function effectively in an actual device and become margins at the time of the formation of memory cell 2. The existence of such portions can be a factor hindering the scale reduction of memory cell 2.

In addition, since bit line oxidized regions 5 are formed through thermal oxidation, dispersion occurs in the width W of the edge portions of buried diffusion bit lines 3. Therefore, the situation occurs wherein the write-in or erasing characteristics of the above described memory cell 2 differ according to each memory cell 2 so that the operational characteristics of memory cell 2 may deteriorate.

Furthermore, a case may occur wherein electrons are trapped in a portion of ONO film 9 placed above a bit line oxidized region 5. In this case, there is a concern that an extra capacitance may occur or that memory cell 2 may malfunction.

### SUMMARY OF THE INVENTION

The present invention is made to solve the above described problems. An object of the present invention is to provide a structure of a non-volatile semiconductor memory device capable of improving the performance and the reliability of the memory cells, while reducing in size of the memory cell, and a manufacturing method for the same.

A non-volatile semiconductor memory device according to the present invention is provided with a semiconductor substrate having a main surface, a first insulating film formed on the main surface and having a charge storage part, first and second impurity diffusion regions formed in the semiconductor substrate located on both sides of the first insulating film, second and third insulating films deposited on the main surface so as to cover the first and second impurity diffusion regions, and a gate electrode formed on the first insulating film.

Since the second and third insulating films are deposited on the main surface of the semiconductor substrate as described above, the situation that the second and third insulating films extend to below the first insulating film so as to push up the edge portions of the first insulating film can be avoided. In addition, the formation of the second and third insulating films can prevent the occurrence of dispersion in the width of the edge portions of the first and second impurity diffusion regions.

The above described first insulating film typically has a lamination structure of a first oxide film, a nitride film and a second oxide film. In this case, the nitride film serves as the charge storage part. Then, it is preferable for the first insulating film to be formed between the second and third insulating films without extending over the second and third insulating films.

A manufacturing method for a non-volatile semiconductor memory device according to one aspect of the present invention is provided with the following steps. A first insulating film having a charge storage part is formed on a main surface of a semiconductor substrate. A mask film is selectively formed on the first insulating film and the first insulating film is patterned by using this mask film. First and second impurity diffusion regions are formed by implanting impurities into the semiconductor substrate by using the above mask film and the patterned first insulating film as a mask. A second insulating film is deposited above the main surface so as to cover the mask film and the first and second impurity diffusion regions. The mask film is exposed and the second insulating film is filled in between the patterned first insulating films by reducing the thickness of the second insulating film starting from the upper surface of the second insulating film. After the mask film is removed, a gate electrode is formed on the first insulating film. Here, in order to reduce the thickness of the second insulating film, CMP (Chemical Mechanical Polishing) or etching back, for example, may be adopted.

Since the second insulating film is deposited on the main surface of the semiconductor substrate, as described above, the second insulating film can be prevented from extending to under the first insulating film and pushing up an end portion of the first insulating film. In addition, the occurrence of dispersion in the width of the edge portions of the first and second impurity diffusion regions can also be prevented.

A manufacturing method for a non-volatile semiconductor memory device according to another aspect of the present invention is provided with the following steps. A first insulating film having a lamination structure of a first oxide film, a nitride film served as a charge storage part, and a second oxide film is formed on a main surface of a semiconductor substrate. A mask film is selectively formed on the first insulating film and the first insulating film is patterned by using the mask film. First and second impurity diffusion regions are formed by implanting impurities into the semiconductor substrate using the mask film and the patterned first insulating film as a mask. The mask film is removed. A second insulating film is deposited over the main surface so as to cover the first and second impurity diffusion regions. The nitride film is exposed and the second insulating film is filled in between the patterned first insulating films by reducing the thickness of the second insulating film starting from the upper surface of the second insulating film. A gate electrode is formed above the first insulating film via a third oxide film.

In the case of this aspect, the second insulating film is deposited on the main surface of the semiconductor substrate and, therefore, the second insulating film can be prevented from extending to under the first insulating film and from pushing up an edge portion of the first insulating film and the occurrence of dispersion in the width of the edge portions of the first and second impurity diffusion regions can also be prevented.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is an equivalent circuit diagram of a memory cell region of a non-volatile semiconductor memory device according to the present invention;

FIG. 2 is a plan view of a portion of the memory cell region of the non-volatile semiconductor memory device according to the present invention;

FIGS. 3A to 3C are cross sectional views along lines 111A, IIIB and IIIC in the memory cell region shown in FIGS. 1 and 2;

FIG. 4 is a cross sectional view of a non-volatile semiconductor memory device according to the first embodiment of the present invention;

FIGS. 5 to 25 are cross sectional views showing the first to twenty-first steps of a manufacturing process for the non-volatile semiconductor memory device shown in FIG. 4;

FIGS. 26 to 35 are cross sectional views showing the first to tenth steps of a manufacturing process for a non-volatile semiconductor memory device according to the second embodiment of the present invention;

FIG. 36 is a cross sectional view of a non-volatile semiconductor memory device according to the third embodiment of the present invention;

FIGS. 37 to 52 are cross sectional views showing the first to sixteenth steps of a manufacturing process for the non-volatile semiconductor memory device shown in FIG. 36;

FIG. 53 is a cross sectional view of a non-volatile semiconductor memory device according to the fourth embodiment of the present invention;

FIGS. 54 to 64 are cross sectional views showing the first to the eleventh steps of a manufacturing process for the non-volatile semiconductor memory device shown in FIG. 53; and

FIG. 65 is a cross sectional view showing a memory cell region of a non-volatile semiconductor memory device according to a prior art.

### DETAILED DESCRIPTION OF THE PREFERRED EMBODIMENTS

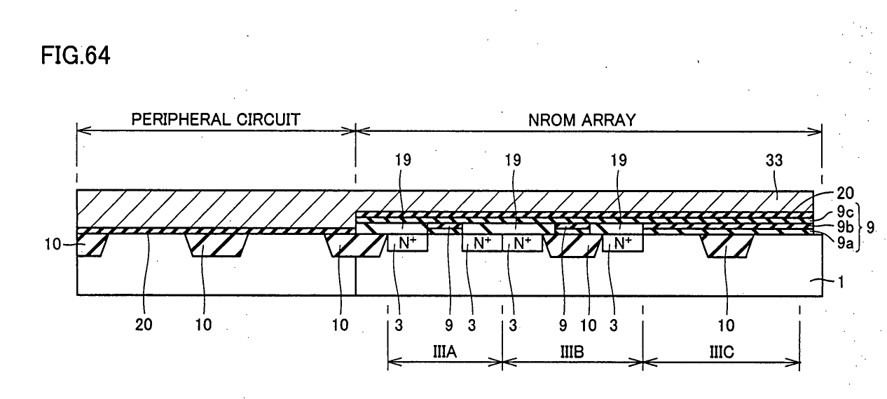

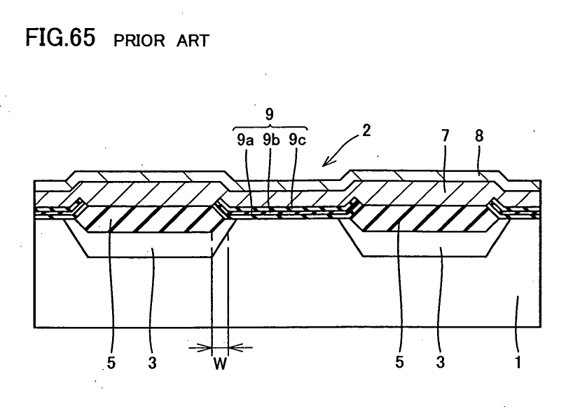

In the following, embodiments of the present invention are described in reference to FIGS. 1 to 64. In the following description, a case is described wherein the present invention is applied in an NROM (Nitrided Read Only Memory) that is an example of a non-volatile semiconductor memory device.

First, a basic structure of an NROM is described. An NROM normally has a memory cell region (memory cell array) wherein memory cells (memory cell transistors) are formed and a peripheral circuit region wherein a peripheral circuit is formed for carrying out operational control of the memory cells.

FIG. 1 shows an equivalent circuit diagram of a memory cell region of an NROM according to the present invention. As shown in FIG. 1, a great number of memory cells are arranged in the memory cell region so that the adjoining memory cells share the sources or the drains.

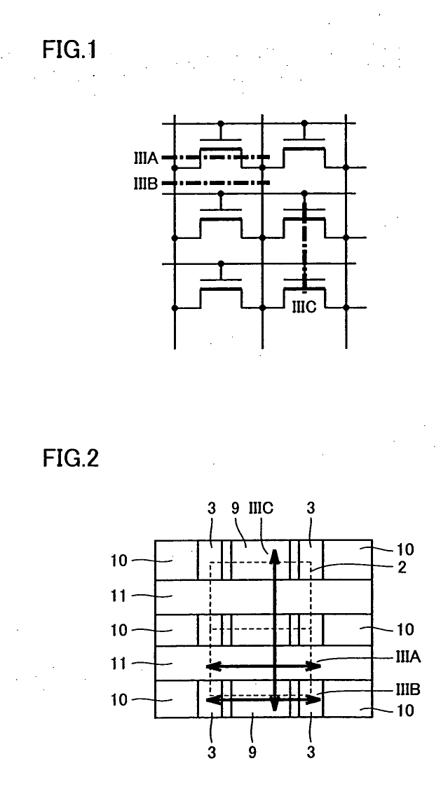

FIG. 2 shows an example of a plan layout of memory cells 2 of the present invention. As shown in FIG. 2, memory cell 2 has a pair of buried diffusion bit lines (impurity diffusion regions) 3 that becomes a source and a drain, an ONO film 9 and a transfer gate electrode 11. In addition, trench isolation regions 10 are provided as element isolation regions around memory cell 2.

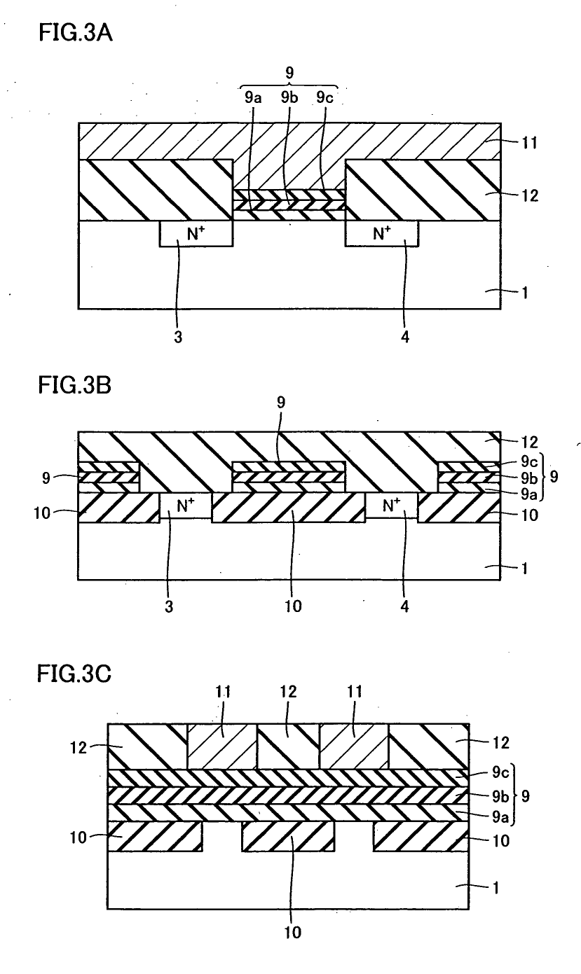

FIGS. 3A to 3C show examples of cross sectional structures along lines 111A, IIIB and 111C in FIGS. 1 and 2.

As shown in FIG. 3A, ONO film 9.1s formed on the main surface of a semiconductor substrate 1. ONO film 9 is formed of an oxide film 9a, a nitride film 9b and an oxide film 9c. Nitride film 9b serves as a charge storage part.

N-type buried diffusion bit lines 3 are formed in semiconductor substrate 1 so as to be located on both sides of ONO film 9. An insulating film 12 is formed on the main surface of semiconductor substrate 1 so as to be located on both sides of ONO film 9 and a transfer gate electrode 11 extends over ONO film 9 and over insulating film 12.

As shown in FIGS. 3B and 3C, trenches are selectively created in the main surface of semiconductor substrate 1 so that insulating films are filled into the trenches, and thereby trench isolation regions 10 are formed. In the cross section shown in FIG. 3B, trench isolation regions 10 are formed on both sides of each buried diffusion bit line 3 and insulating film 12 extends over ONO film 9.

(First Embodiment)

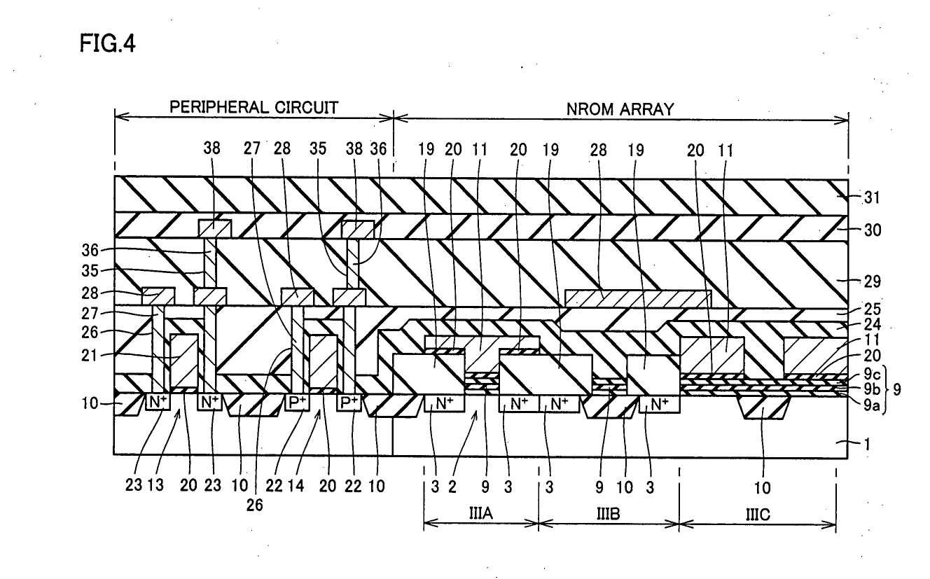

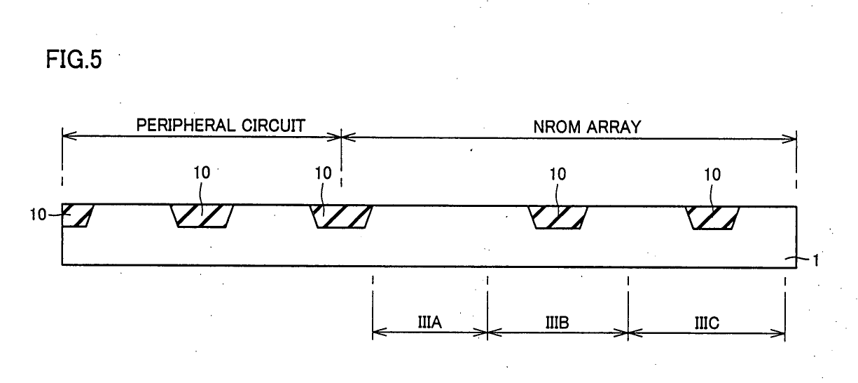

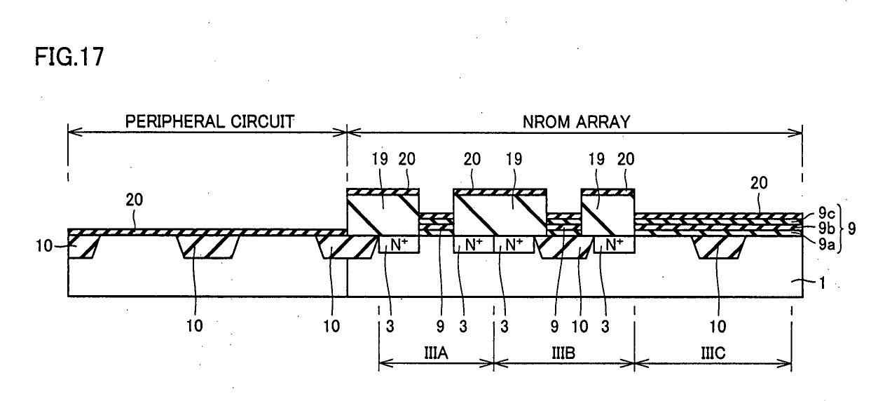

Next, the first embodiment of the present invention is described in reference to FIGS. 4 to 25. FIG. 4 is a cross sectional view of an NROM according to the present first embodiment. Here, the cross sectional structures along the above described lines IIIA, IIIB and IIIC are respectively shown in the NROM array (memory cell region) of FIG. 4.

As shown in FIG. 4, the NROM has a peripheral circuit region and an NROM array. An NMOS Metal Oxide Semiconductor) transistor 13 and a PMOS transistor 14 are formed in semiconductor substrate 1 within the peripheral circuit region and a memory cell 2 is formed in semiconductor substrate 1 within the NROM array. Trench isolation regions 10 are selectively formed in the main surface of semiconductor substrate 1.

Memory cell 2 has a pair of buried diffusion bit lines (first and second impurity diffusion regions) 3, an ONO film (first insulating film) 9 and a transfer gate electrode 11. The two buried diffusion bit lines 3, which make up the pair, are formed, with an interval between them, in semiconductor substrate 1 and include a high concentration of N-type impurities.

Oxide films (second and third insulating films) 19 are formed on buried diffusion bit lines 3 on both sides of ONO film 9. The present invention has the important characteristic that oxide films 19 are formed through deposition on the main surface of semiconductor substrate 1. Thereby, the state wherein oxide films 19 extend to beneath ONO film 9 so as to push up the edge portions of ONO film 9 can be avoided and portions in the vicinity of the edge portions of ONO film 9 can be prevented from becoming unnecessary portions in memory cell 2. As a result, the portions that would become unnecessary portions in memory cell 2 can be eliminated so that miniaturization of the memory cell becomes easy.

In addition, oxide films 19 are formed through deposition of an oxide film and, therefore, these oxide films 19 do not invade buried diffusion bit lines 3. Therefore, the occurrence of dispersion in the width of the edge portions of buried diffusion bit lines 3 can be prevented.

Furthermore, a flattening process, such as CPM, is carried out on oxide films 19 which, therefore, attain a thickness that is substantially uniform in the direction parallel to the main surface of semiconductor substrate 1 and which have a flat upper surface. Thus, the base of transfer gate electrode 11 becomes flat so that the formation of transfer gate electrode 11 becomes easy.

Transfer gate electrode 11 is formed of a conductive film such as a polysilicon film wherein impurities are doped and is formed on ONO film 9 via an oxide film 20. In addition, transfer gate electrode 11 extends from the area above ONO film 9 to the areas above oxide films 19.

NMOS transistor 13 has N-type impurity diffusion regions 23 that become source/drain, an oxide film 20 that becomes a gate insulating film and a gate electrode 21. PMOS transistor 14 has P-type impurity diffusion regions 22 that become source/drain, an oxide film 20 that becomes a gate insulating film and a gate electrode 21.

Interlayer insulating films 24 and 25 are formed so as to cover memory cell 2, NMOS transistor 13 and PMOS transistor 14. Contact holes 26 are created so as to penetrate interlayer insulating films 24 and 25 and so as to reach to P-type impurity diffusion regions 22 and N-type impurity diffusion regions 23, and plug electrodes 27 are formed within these contact holes 26.

First metal wires 28 made of a material that includes Al are formed on plug electrodes 27 and on interlayer insulating film 25 and, then, an interlayer insulating film 29 is formed so as to cover first metal wires 28. Via holes 35 are created in this interlayer insulating film 29 and plug electrodes 36 are formed within via holes 35.

Second metal wires 38 made of a material that includes Al are formed on plug electrodes 36 and on interlayer insulating film 29 and, then, an interlayer insulating film 30 is formed so as to cover second metal wires 38. A polyimide film 31 is formed on this interlayer insulating film 30.

Next, a manufacturing method for the NROM having the above described structure is described in reference to FIGS. 5 to 25.

First, etching or the like is selectively carried out on the main surface of a semiconductor substrate 1, and thereby trenches are created. An insulating film such as an oxide film is filled into these trenches by means of, for example, a CVD (Chemical Vapor Deposition) method. After that, CMP (Chemical Mechanical Polishing) or the like is carried on the insulating film, and thereby trench isolation regions 10 are formed as shown in FIG. 5.

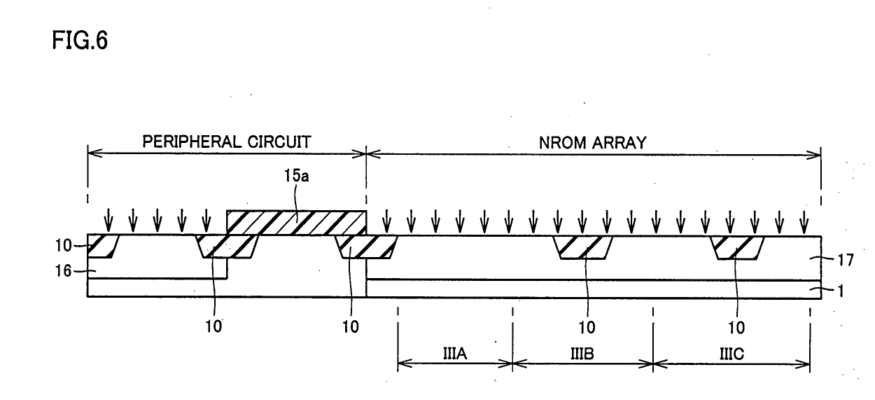

Next, implantation of impurities is carried out in order to form triple well structures in the peripheral circuit region and in the NROM array (memory cell region). As shown in FIG. 6, a resist 15a is selectively formed on the main surface of semiconductor substrate 1 and N-type impurities are implanted into semiconductor substrate 1 by using resist 15a as a mask. Thereby, bottom N well regions 16 and 17 having triple well structures are formed.

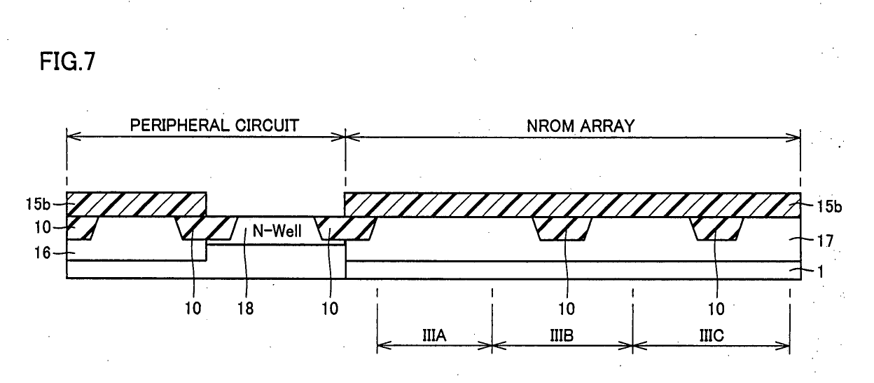

In addition, as shown in FIG. 7, a resist 15b is applied on the main surface of semiconductor substrate 1 and, then, resist 15b is patterned to a predetermined form by means of a photomechanical (photolithography) process. N-type impurities are implanted into semiconductor substrate 1 by using this resist 15b as a mask, and thereby an N well region 18 is formed.

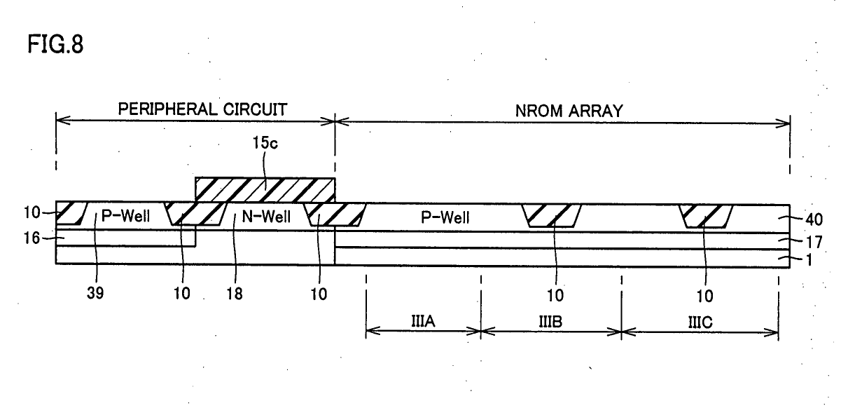

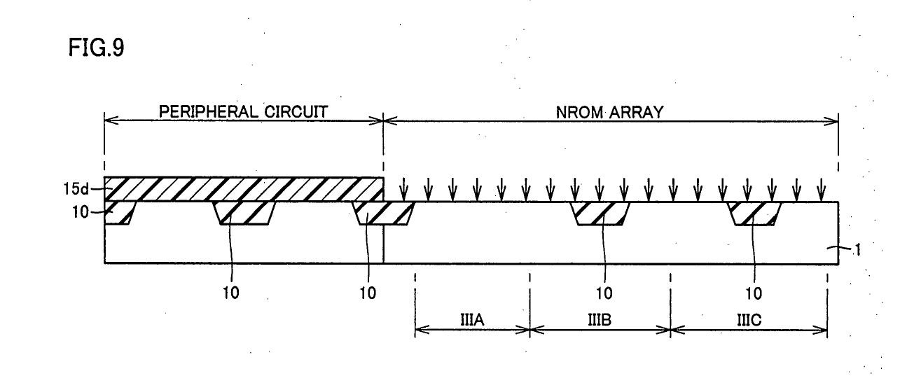

Furthermore, as shown in FIG. 8, a resist 15c is formed on the main surface of semiconductor substrate 1 and P-type impurities are implanted into semiconductor substrate 1 by using resist 15c as a mask, and thereby P well regions 39 and 40 are formed.

Next, as shown in FIG. 9, a resist 15d is formed so as to cover the peripheral circuit region and predetermined impurities are implanted into semiconductor substrate 1 located within the memory cell region by using resist 15d as a mask. Thereby, the threshold voltage (Vth) of memory cell 2 is adjusted.

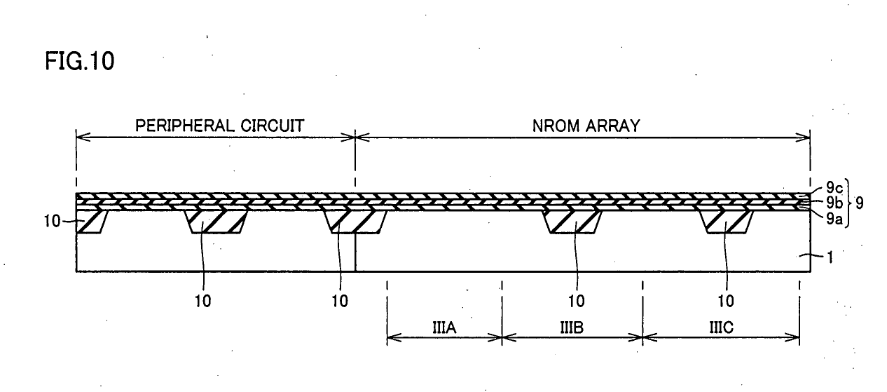

After that, as shown in FIG. 10, an ONO film 9 is formed on the main surface of semiconductor substrate 1. For example, a silicon oxide film is formed by thermally oxidizing the main surface of semiconductor substrate 1 and a silicon nitride film is formed on this silicon oxide film by means of a CVD method or the like, and then a silicon oxide film is formed on the silicon nitride film by means of a CVD method or the like. Thereby, ONO film 9 made up of a lamination structure of an oxide film 9a, a nitride film 9b and an oxide film 9c can be formed.

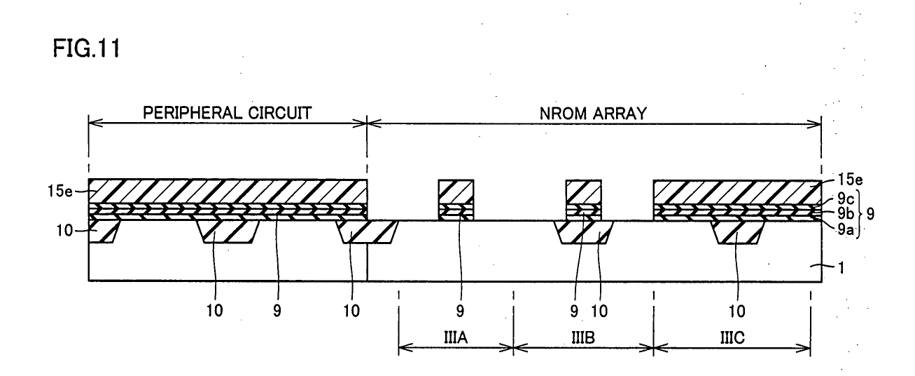

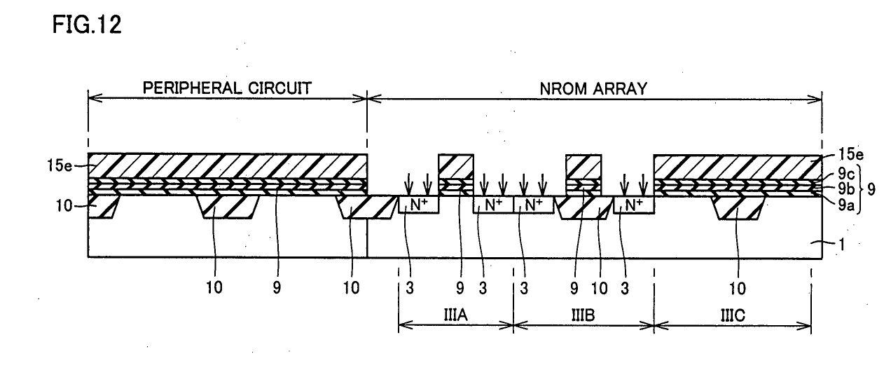

Next, a resist is applied to ONO film 9 and the resist is patterned through a photomechanical process. Thereby, as shown in FIG. 11, a resist (mask film) 15e is formed that covers ONO film 9 above the portions other than the portions that become source and drain regions (buried diffusion bit lines 3) of memory cell 2. ONO film 9 is etched by using this resist 15e as a mask so as to selectively expose the main surface of semiconductor substrate 1. N-type impurities are implanted into the main surface of semiconductor substrate 1 under such a condition, and thereby, as shown in FIG. 12, buried diffusion bit lines 3 are formed.

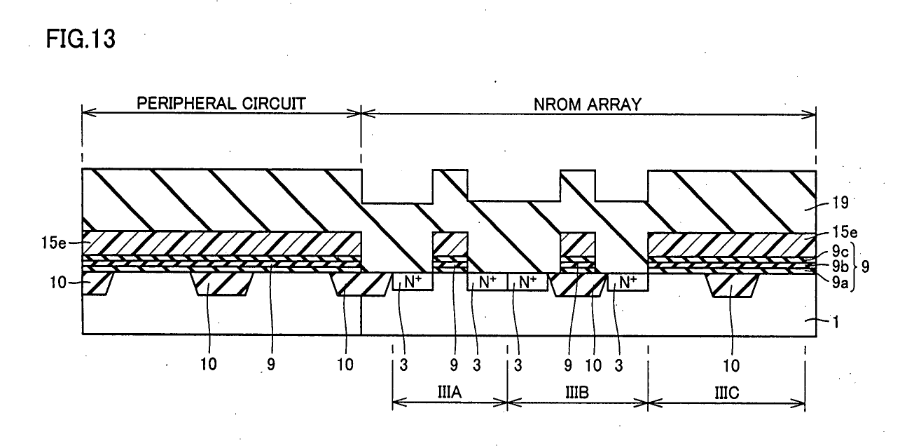

Next, as shown in FIG. 13, an oxide film (typically silicon oxide film) 19 is deposited over the main surface of semiconductor substrate 1 by means of a CVD method or the like. After that, the thickness of this oxide film 19 is reduced, starting from the upper surface of oxide film 19. The thickness of oxide film 19 can be reduced by carrying out CMP or etching back, for example.

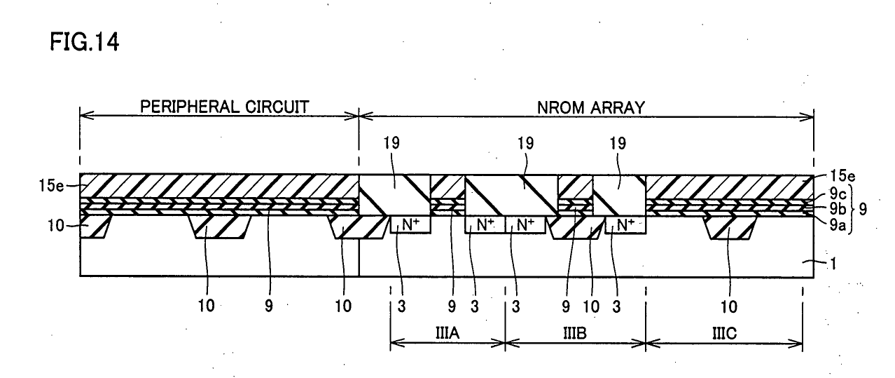

At this time, the process of reducing the thickness, such as by CMP or etching back, can be stopped at resist 15e, of which the material differs from that of oxide film 19. Thereby, as shown in FIG. 14, resist 15e is exposed and oxide films 19 can be deposited on buried diffusion bit lines 3.

Here, a mask film made of a material differing from that of oxide film 19, for example an insulating film such as a silicon nitride film that is not an oxide film, a conductive film, a high melt point metal film or a film consisting of layers of these can be utilized for the mask film of the present invention.

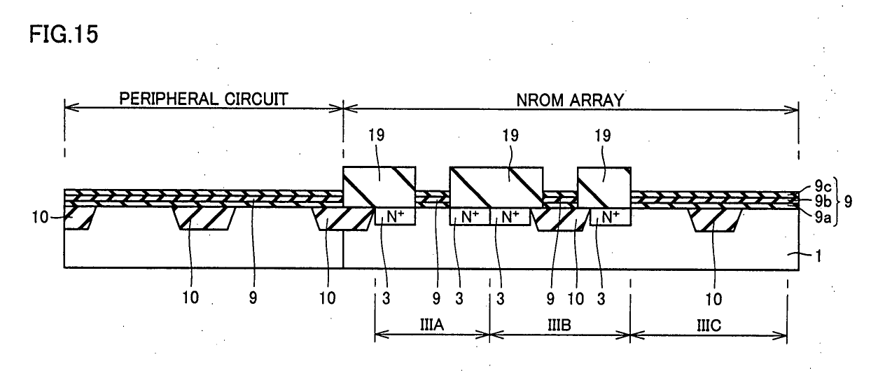

Next, as shown in FIG. 15, resist 15e is removed. Thereby, oxide film 19 having a thickness greater than that of ONO film 9 and having a uniform thickness can be formed on buried diffusion bit lines 3.

Since oxide film 19 is deposited on semiconductor substrate 1 as described above, it is not necessary to grow an oxide film on buried diffusion bit lines 3 by means of a heat treatment such as in a prior art. Thereby, oxide films 19 do not invade or penetrate beneath ONO film 9 and edge portions of ONO film 9 do not become of a raised condition.

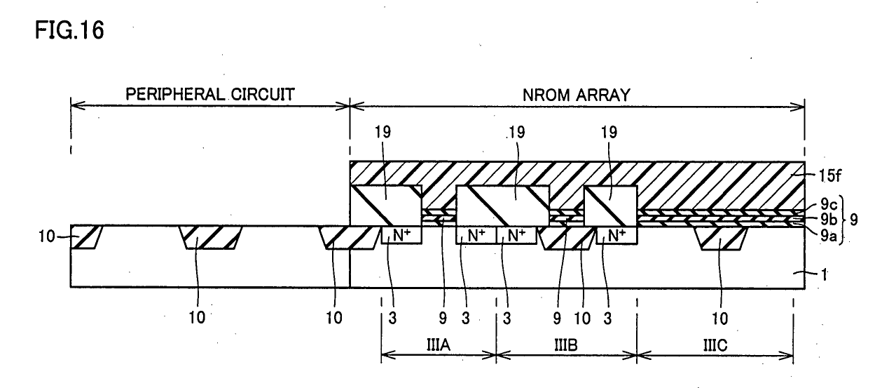

Next, as shown in FIG. 16, a resist 15f is formed so as to cover the memory cell region and to expose the peripheral circuit region in order to form elements of the peripheral circuit. ONO film 9 in the peripheral circuit region is removed by using this resist 15f as a mask. After that, resist 15f is removed.

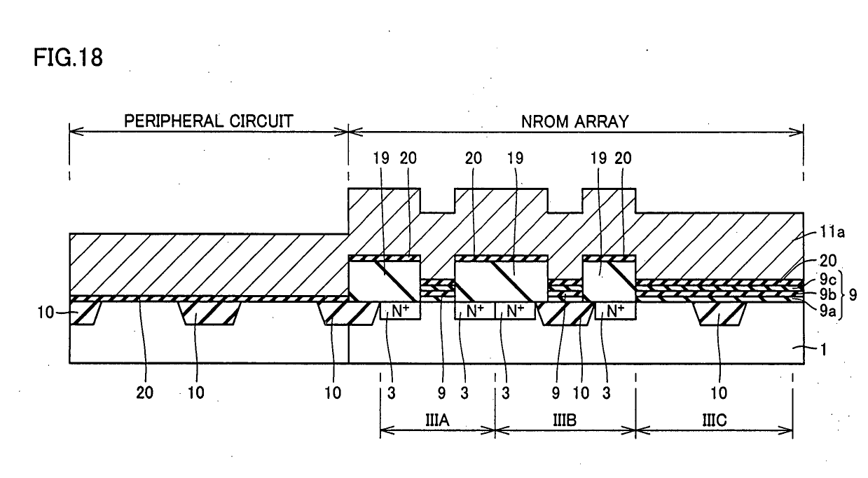

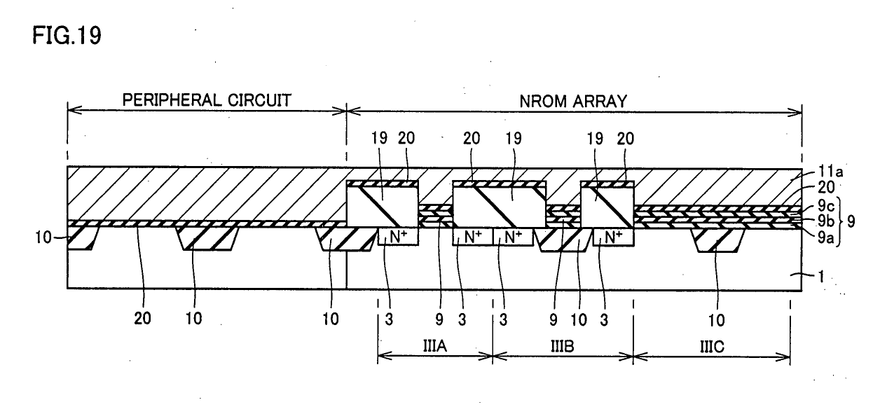

Next, an oxide film 20 is formed by means of thermal oxidation, a CVD method or the like. This oxide film 20 becomes a gate insulating film of NMOS transistor 13 and PMOS transistor 14 in the peripheral circuit region. A polysilicon film 11a into which impurities are doped is formed over this oxide film 20 by means of a CVD method or the like, as shown in FIG. 18. CMP is carried out on this polysilicon film 1a so that the upper surface of polysilicon film 11a is flattened, as shown in FIG. 19.

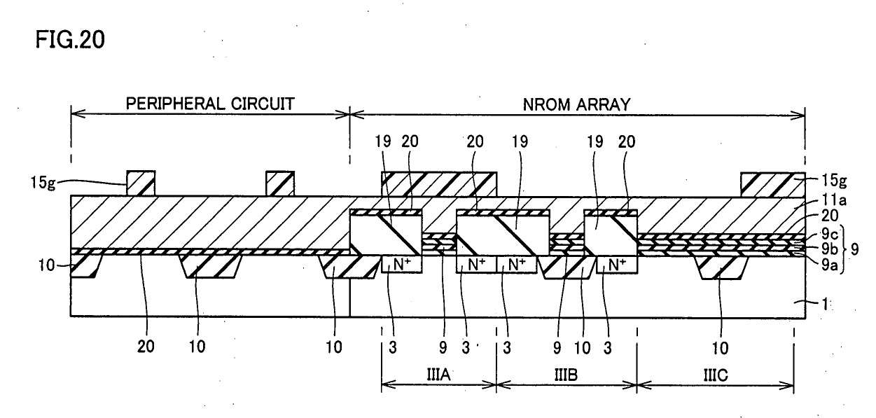

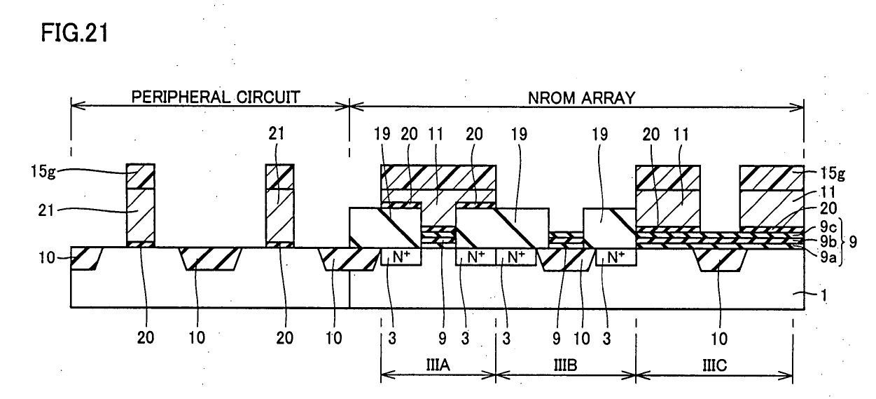

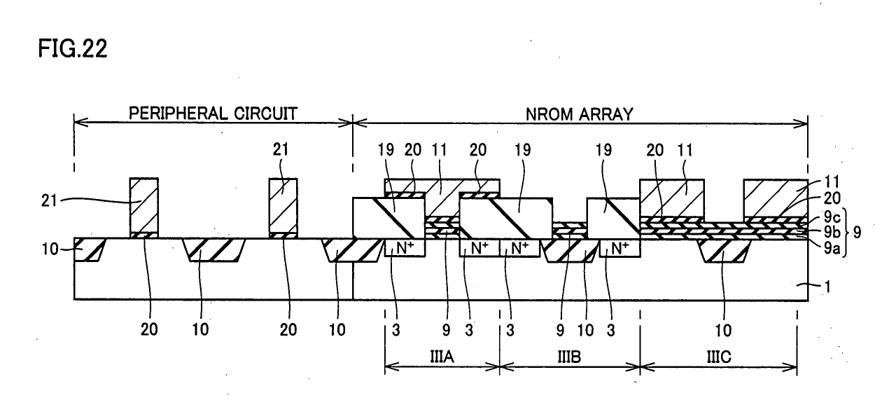

As shown in FIG. 20, a resist 15g is formed on polysilicon film 11a and polysilicon film 11a is etched by using resist 15g as a mask. Thereby, as shown in FIG. 21, transfer gate electrodes 11 are formed in the memory cell region and, at the same time, gate electrodes 21 of NMOS transistor 13 and PMOS transistor 14 can be formed in the peripheral circuit region. After that, as shown in FIG. 22, resist 15g is removed.

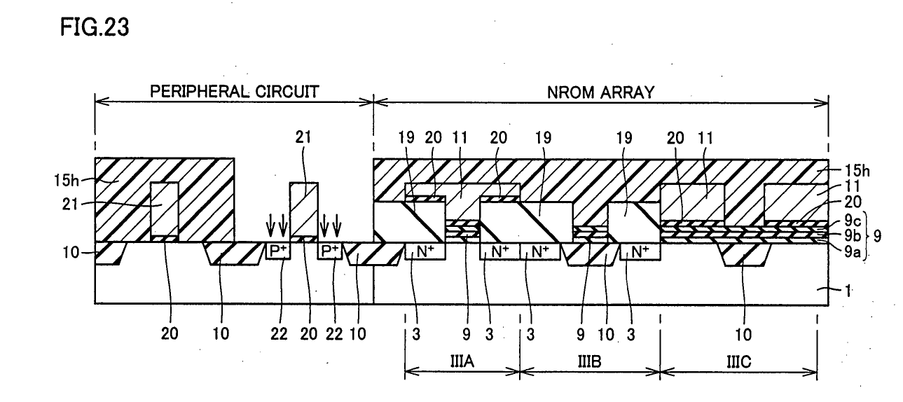

Next, as shown in FIG. 23, a resist 15h that exposes the region for forming PMOS transistor 14 and P-type impurities, such as boron, are implanted into semiconductor substrate 1 by using this resist 15h as a mask. Thereby, P-type diffusion regions 22, which become the source and the drain of PMOS transistor 14, are formed. After that, resist 15h is removed.

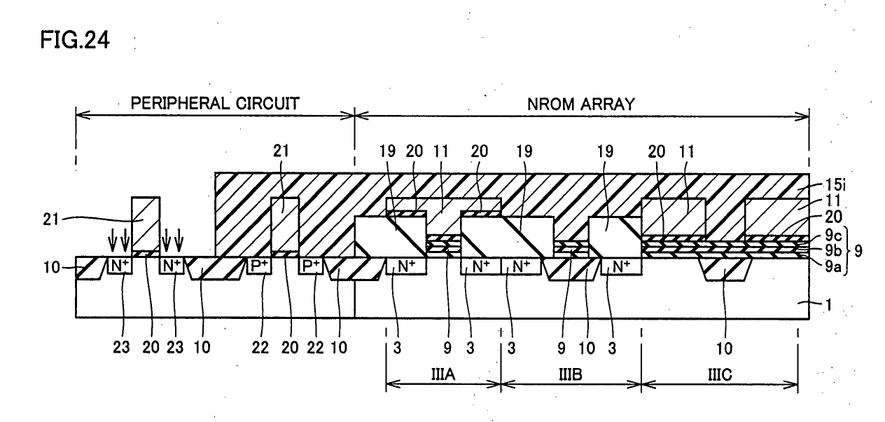

Next, as shown in FIG. 24, resist 15i, which exposes the region for forming NMOS transistor 13 is formed and N-type impurities, such as arsenic, are implanted into semiconductor substrate 1 by using this resist 15i as a mask. Thereby, N-type diffusion regions 23, which become the source and the drain of NMOS transistor 13, are formed. After that, resist 15i is removed.

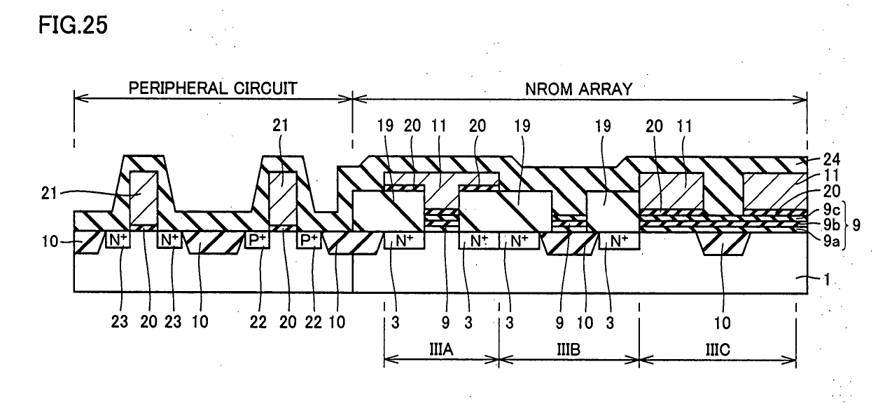

Next, as shown in FIG. 25, an interlayer insulating film 24, such as an oxide film, is formed by means of a CVD method or the like. After that, interlayer insulating films 25, 29 and 30, contact holes 26, plug electrodes 27 and 36, first metal wires 28, via holes 35, second metal wires 38 and polyimide film 31 are formed by means of well-known techniques so that the NROM shown in FIG. 4 is gained.

(Second Embodiment)

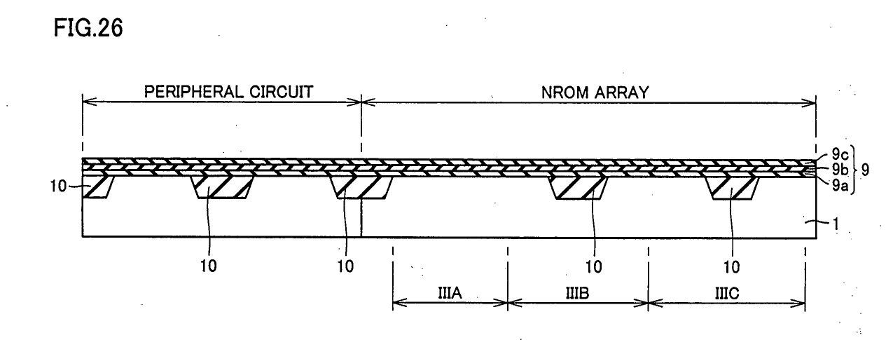

Next, the second embodiment of the present invention is described in reference to FIGS. 26 to 35. Here, the structure of the NROM according to the present second embodiment is the same as in the first embodiment, of which the illustration and the description are omitted.

In the present second embodiment, an example is described wherein a metal, such as aluminum or copper, or a semiconductor, such as polysilicon, is used for a mask film of the present invention.

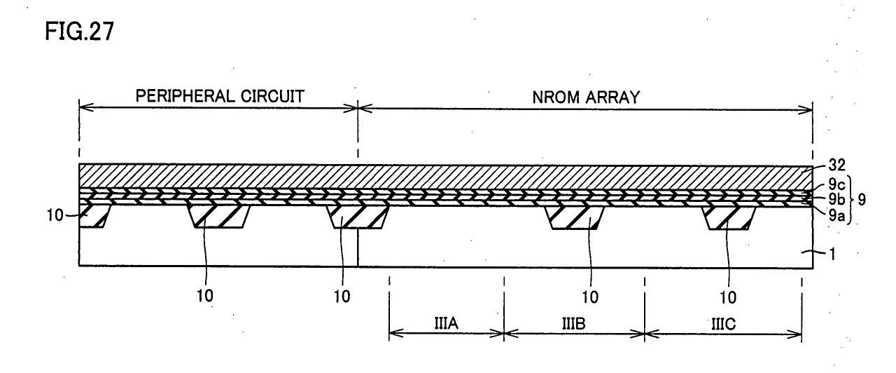

As shown in FIG. 26, trench isolation regions 10 are formed in the main surface of semiconductor substrate 1 by the same techniques as in the first embodiment and an ONO film 9 is formed on this main surface. A metal film 32, such as of aluminum or of copper, is formed on this ONO film 9 by means of a sputtering method or the like, as shown in FIG. 27.

Here, a semiconductor film, such as a polysilicon film, may be formed by means of a CVD method or the like instead of metal film 32. In this case, the quality of ONO film 9 can be improved by carrying out a heat treatment after the formation of the polysilicon film.

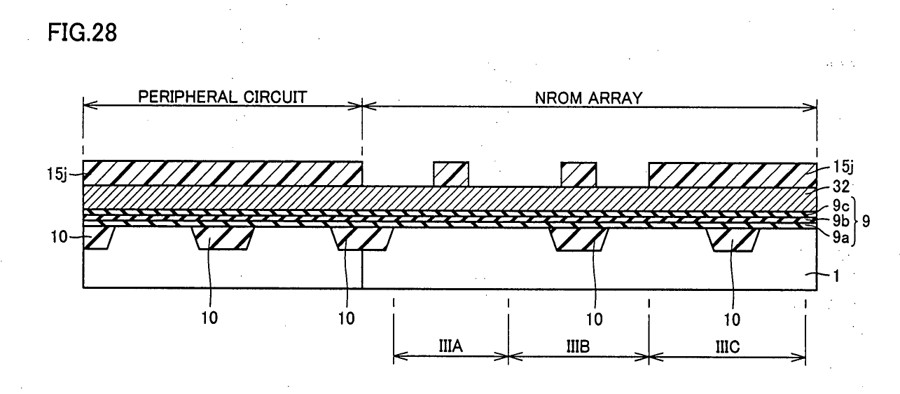

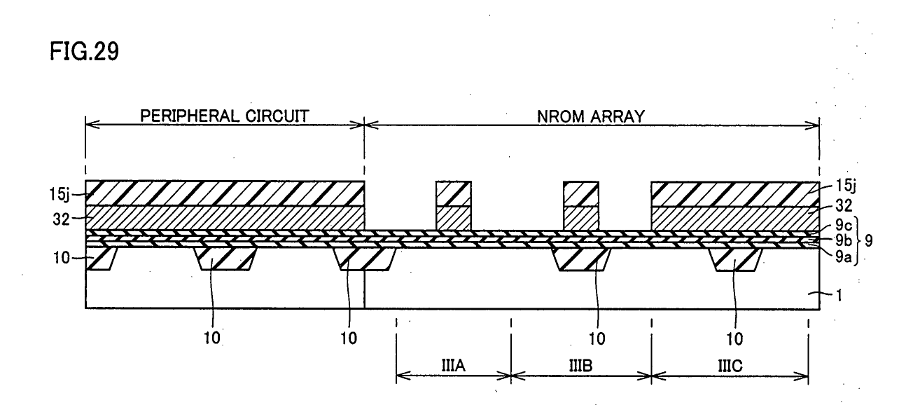

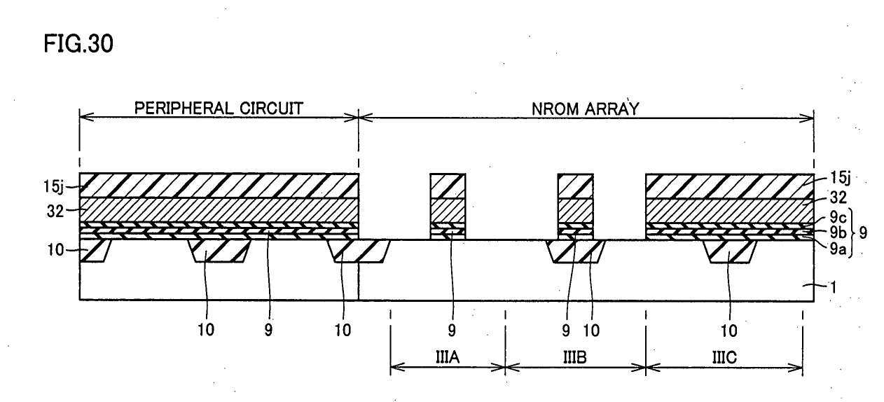

As shown in FIG. 28, a resist 15j that exposes metal film 32 located above the regions for forming the source and the drain of memory cell 2 is formed on metal film 32. Metal film 32 and ONO film 9 are sequentially etched, as shown in FIGS. 29 and 30, by using this resist 15j as a mask. Thereby, the regions for forming the source and the drain of memory cell 2 in semiconductor substrate 1 are exposed.

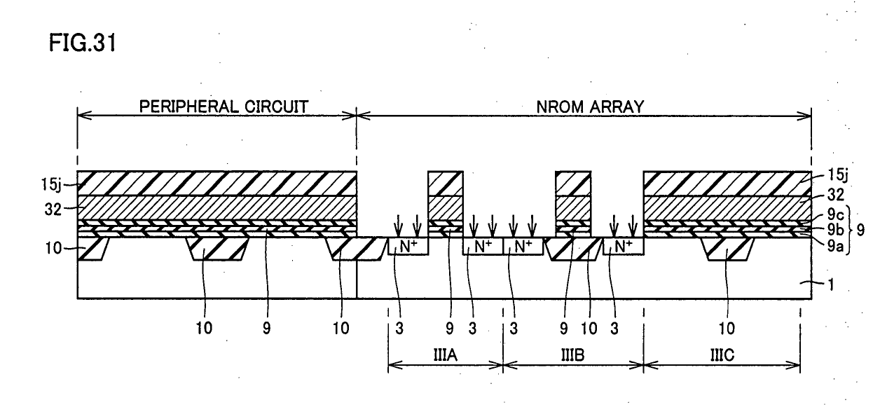

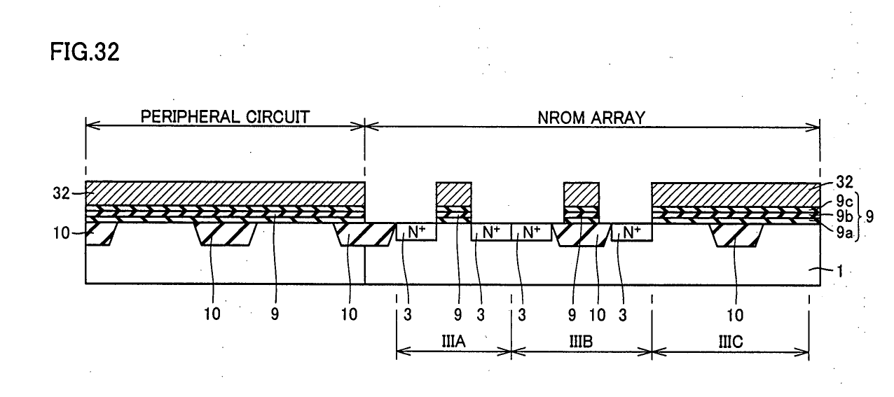

Next, as shown in FIG. 31, N-type impurities are implanted into semiconductor substrate 1 by using resist 15j and metal film 32 as a mask. Thereby, buried diffusion bit lines 3, which become the source and the drain of memory cell 2, can be formed. After that, resist 15j is removed, as shown in FIG. 32.

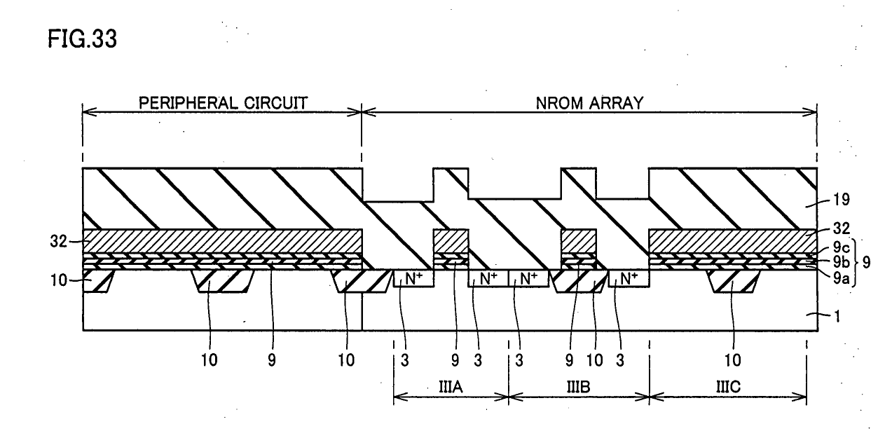

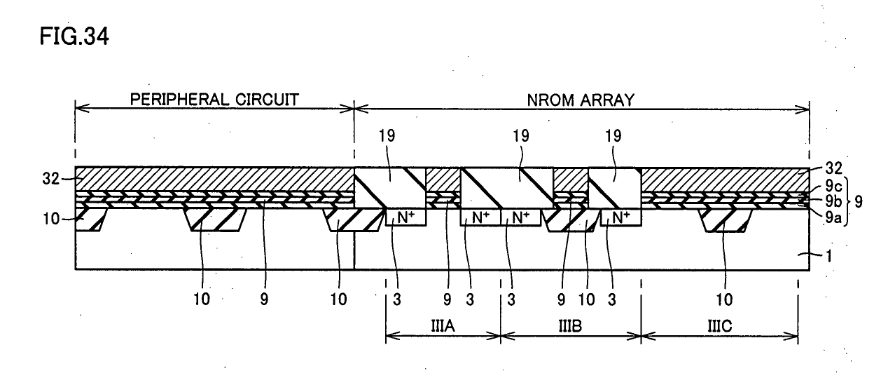

Next, as shown in FIG. 33, an oxide film 19 is deposited over the entirety of the surface of semiconductor substrate 1 so as to cover metal film 32 by means of a CVD method or the like. A thickness reduction process is carried out on this oxide film 19 by means of the same technique as in the first embodiment, as shown in FIG. 34. At this time, this thickness reduction process can be stopped at metal film 32 or at the polysilicon film. As a result, oxide films 19 can be filled in between ONO films 9 in the same manner as in the first embodiment so that the same effects as of the first embodiment can be gained.

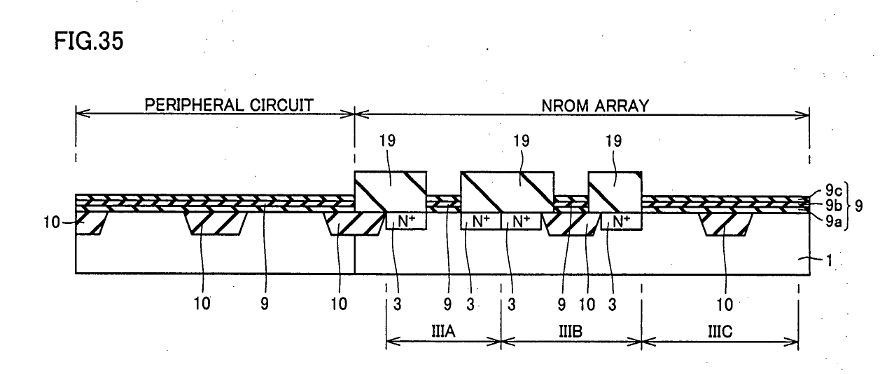

After that, as shown in FIG. 35, metal film 32 is removed. Hereinafter, the same process as in the first embodiment is carried out so as to gain the NROM of the present second embodiment.

(Third Embodiment)

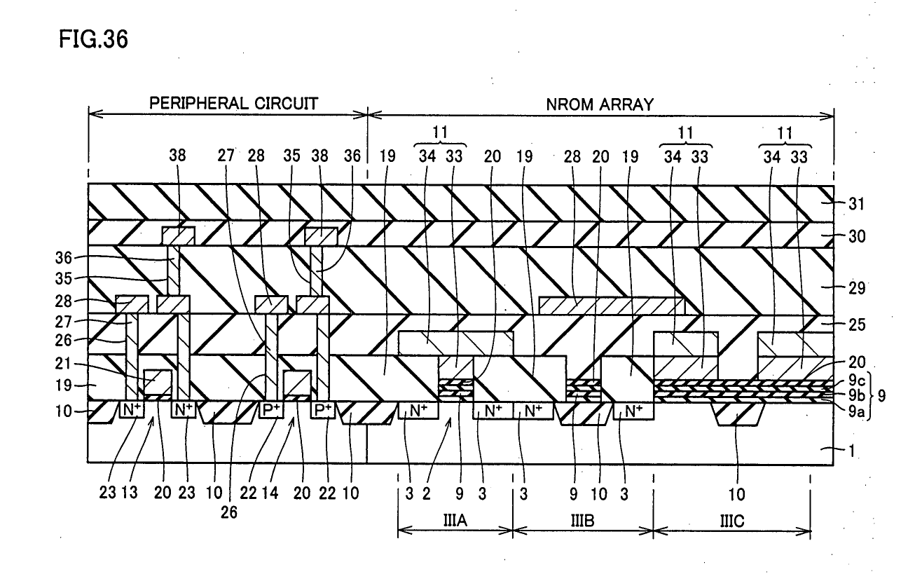

Next, the third embodiment of the present invention is described in reference to FIGS. 36 to 52. FIG. 36 is a cross sectional view of an NROM according to the present third embodiment.

In the NROM according to the third embodiment, as shown in FIG. 36, a transfer gate electrode 11 of a memory cell 2 has a lamination structure of polysilicon films 33 and 34 while the thickness of the gates of NMOS transistor 13 and PMOS transistor 14 in a peripheral circuit is smaller than the thickness of those in the first embodiment. The structures of the other parts are substantially the same as in the case of the first embodiment, of which the descriptions are omitted.

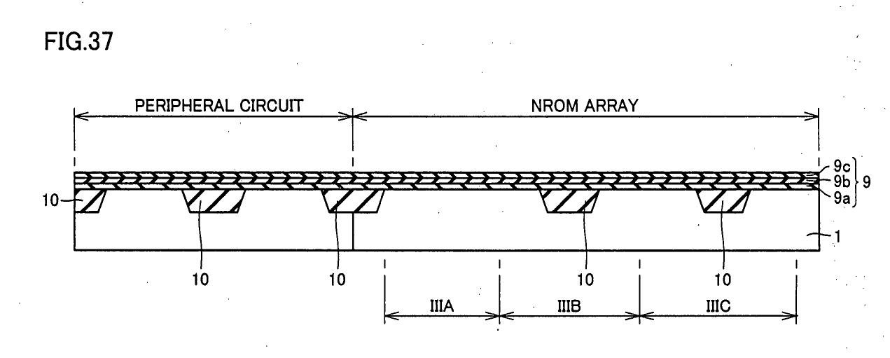

Next, a manufacturing method for an NROM according to the present third embodiment is described in reference to FIGS. 37 to 52.

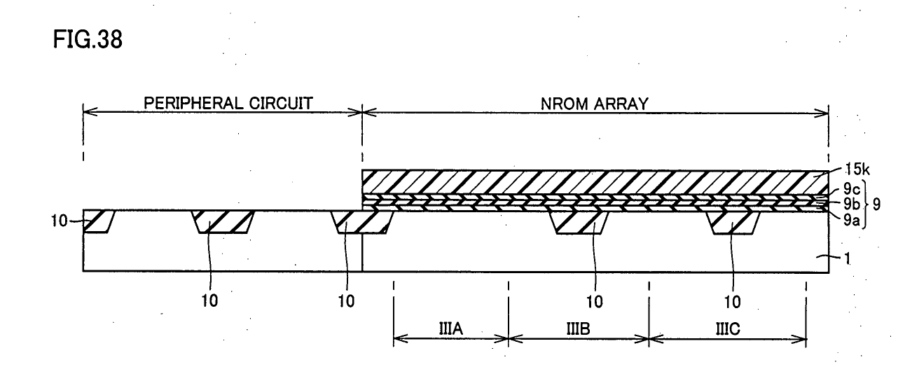

As shown in FIG. 37, trench isolation regions 10 are formed in the main surface of a semiconductor substrate 1 by means of the same technique as in the first embodiment and an ONO film 9 is formed on this main surface. A resist is applied to this ONO film 9 and a resist 15k that covers a memory cell region is formed by means of a photomechanical process. ONO film 9 is etched by using this resist 15k as a mask, and thereby the main surface of semiconductor substrate 1 in a peripheral circuit region is exposed as shown in FIG. 38.

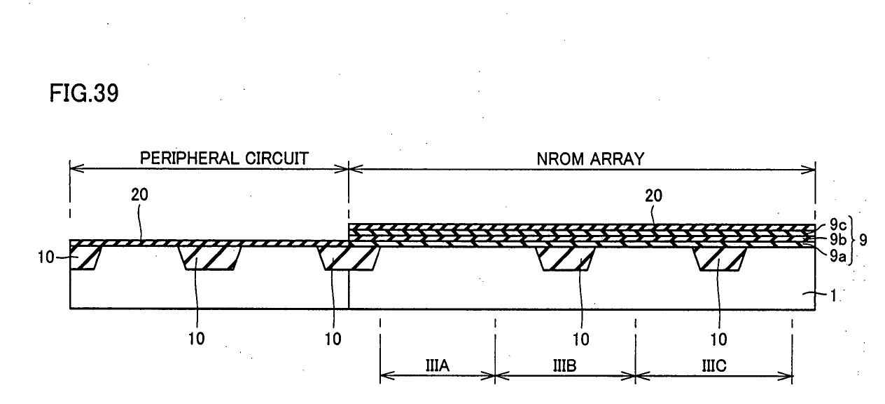

After removing resist 15k, as shown in FIG. 39; an oxide film 20 is formed by means of a thermal oxidation method, a CVD method or the like. This oxide film 20 becomes gate insulating films of NMOS transistor 13 and PMOS transistor 14 in the peripheral circuit.

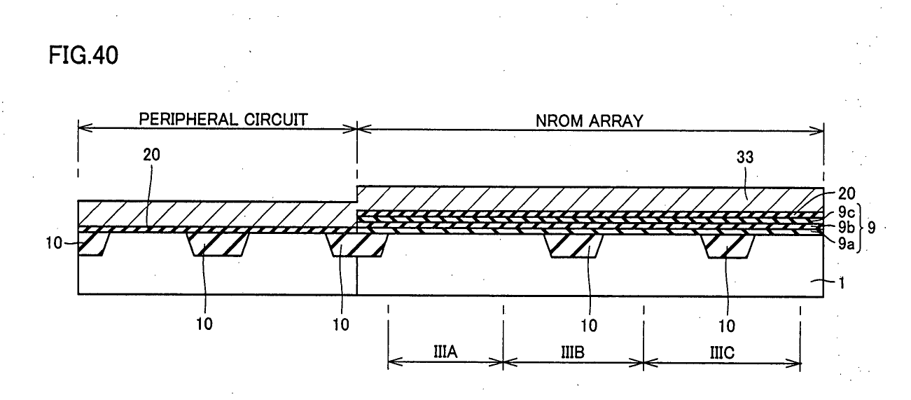

Next, as shown in FIG. 40, a polysilicon film (mask film) 33 into which impurities are doped is formed on oxide film 20 by means of a CVD method or the like. This polysilicon film 33 becomes gate electrodes of NMOS transistor 13 and PMOS transistor 14 in the peripheral circuit and becomes a lower layer gate portion of transfer gate electrode 11 in the memory cell region.

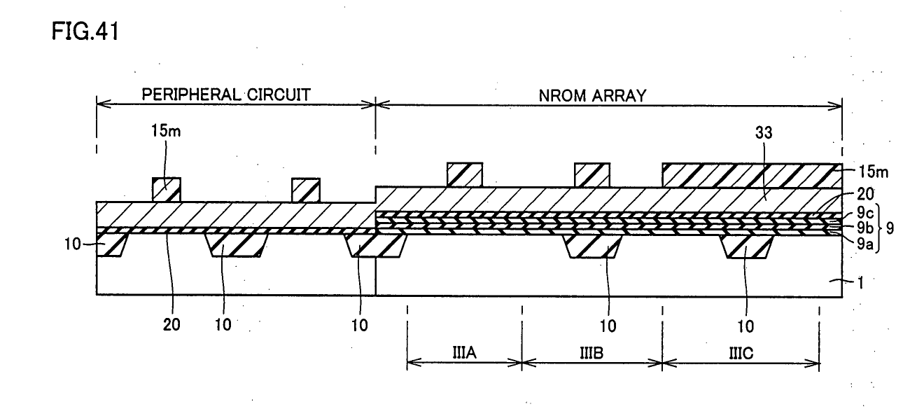

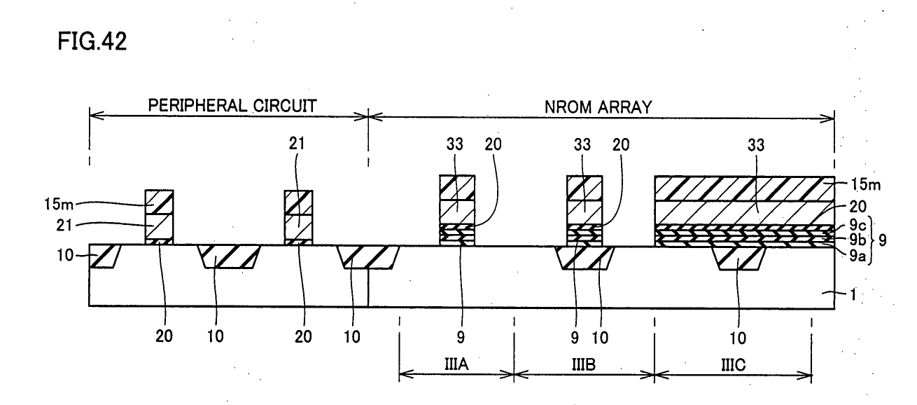

As shown in FIG. 41, a resist 15m is formed on polysilicon film 33 having openings above the regions wherein a source and a drain of NMOS transistor 13 are formed, above the regions wherein a source and a drain of PMOS transistor 14 are formed in the peripheral circuit and above the regions wherein a source and a drain of memory cell 2 are formed. Polysilicon film 33, oxide film 20 and ONO film 9 are etched, as shown in FIG. 42, by using this resist 15m as a mask.

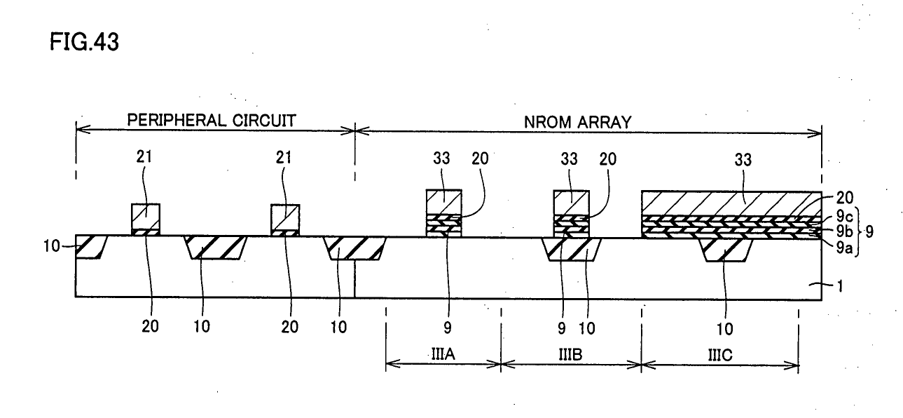

After that, as shown in FIG. 43, resist 15m is removed. Thereby, gate electrodes 21 of NMOS transistor 13 and PMOS transistor 14 in the peripheral circuit are formed and a lower layer gate portion of transfer gate electrode 11 of memory cells 2 is formed.

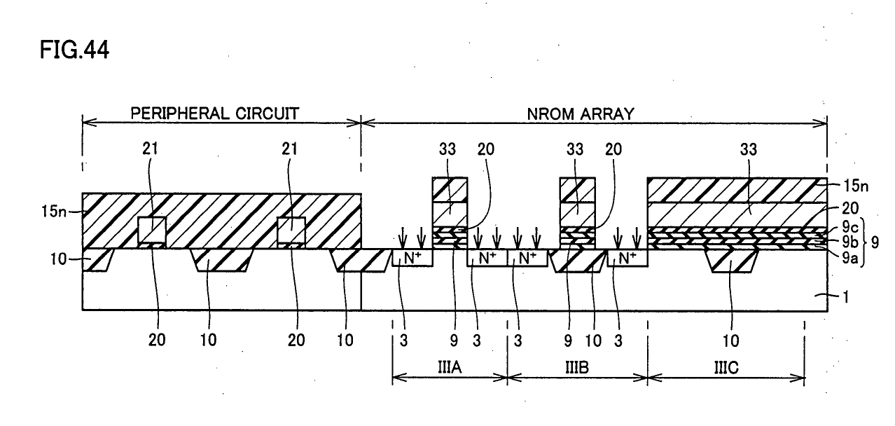

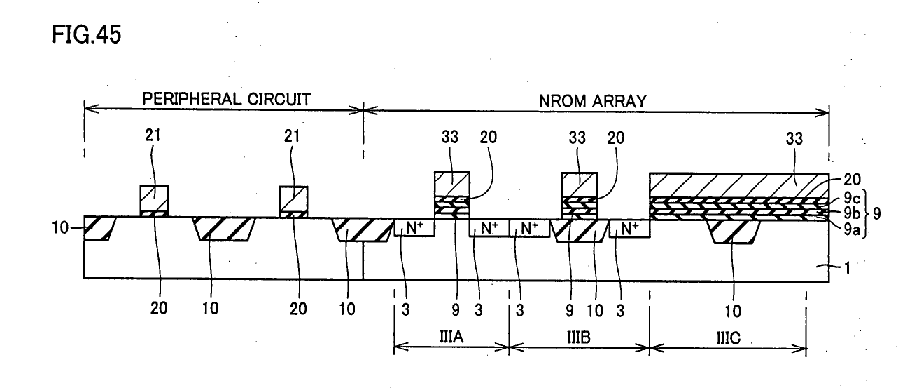

Next, a resist 15n for exposing regions wherein a source and a drain (buried diffusion bit lines 3) of memory cell 2 are formed. N-type impurities are implanted into semiconductor substrate 1 by using this resist 15n as a mask. Thereby, as shown in FIG. 44, buried diffusion bit lines 3 are formed. After that, as shown in FIG. 45, resist 15n is removed.

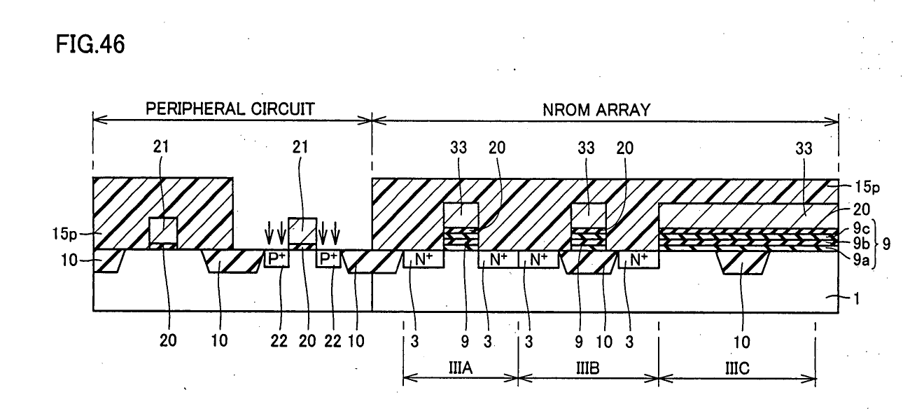

Next, as shown in FIG. 46, a resist 15p for exposing the region, wherein PMOS transistor 14 is formed, is formed and P-type impurities such as boron are implanted into semiconductor substrate 1 by using this resist 15p as a mask. Thereby, P-type diffusion regions 22 that become the source and the drain of PMOS transistor 14 are formed. After that, resist 15p is removed.

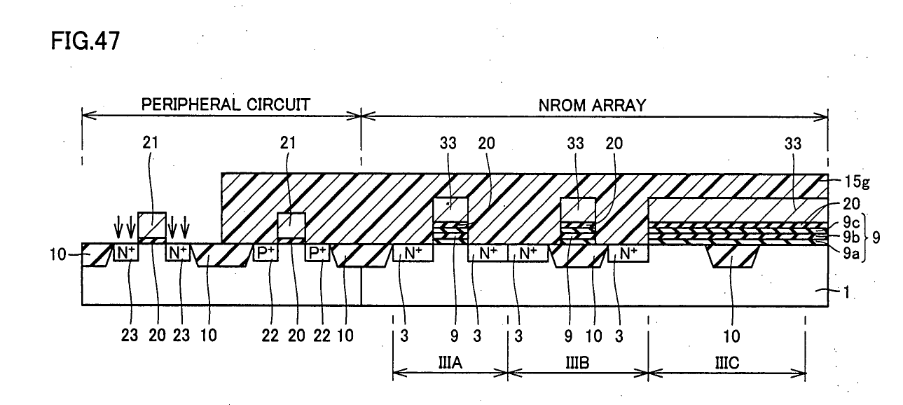

Next, as shown in FIG. 47, a resist 15q for exposing the region, wherein NMOS transistor 13 is formed, is formed and N-type impurities such as arsenic are implanted into semiconductor substrate 1 by using this resist 15q as a mask. Thereby, N-type diffusion regions 23 that become the source and the drain of NMOS transistor 13 are formed. After that, resist 15q is removed.

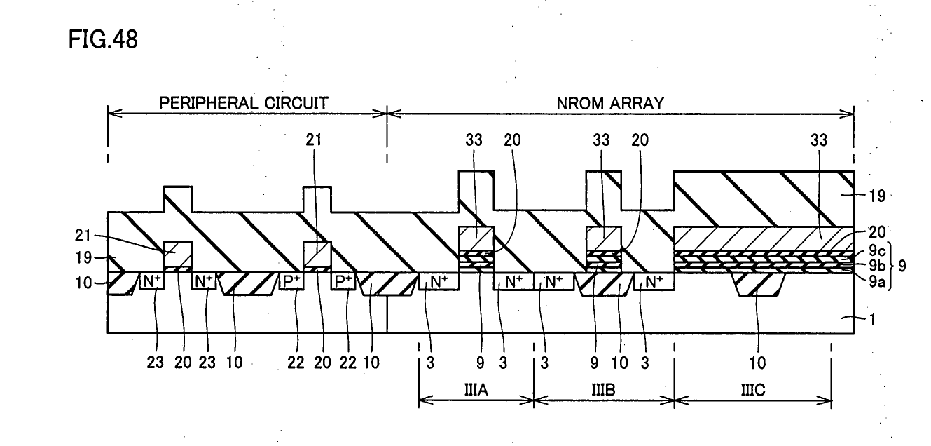

Next, as shown in FIG. 48, an oxide film 19, such as a silicon oxide film, is deposited over the main surface of semiconductor substrate 1 by means of a CVD method or the like. A thickness reduction process, starting from the upper surface of this oxide film 19, is carried out on this oxide film 19 by means of the same technique as in the first embodiment.

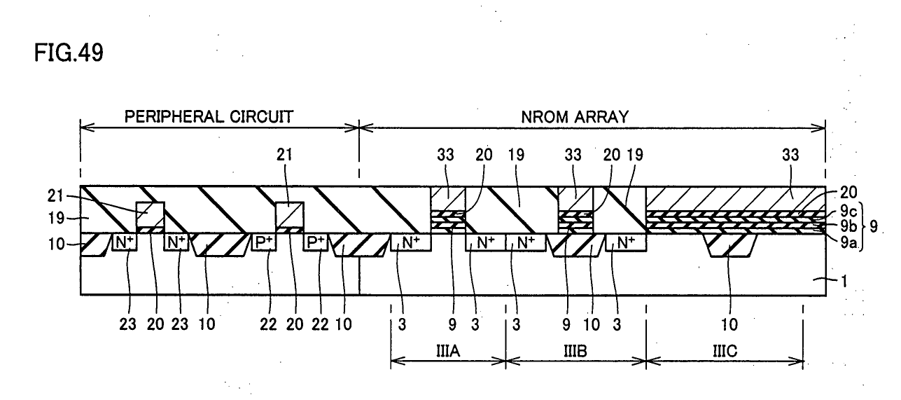

At this time, the thickness reduction process, such as CMP, etching back or the like can be stopped at polysilicon film 33, which is made of a material that is different from that of oxide film 19. That is to say, polysilicon film 33 functions as a mask film at the time of the patterning of ONO film 9 in the memory cell region and also functions as a stopper film in the above described thickness reduction process. As shown in FIG. 49, polysilicon film 33 is exposed, oxide films 19 can be formed on buried diffusion bit lines 3 and the upper surfaces of oxide films 19 can be flattened through this thickness reduction process.

Thus, in the present third embodiment, polysilicon film 33 functions as a mask film at the time of the patterning of ONO film 9 and functions as a stopper in the above described thickness reduction process and, in addition, becomes gate electrodes of NMOS transistor 13 and PMOS transistor 14 and, moreover, becomes a lower gate portion of a gate electrode of memory cell 2.

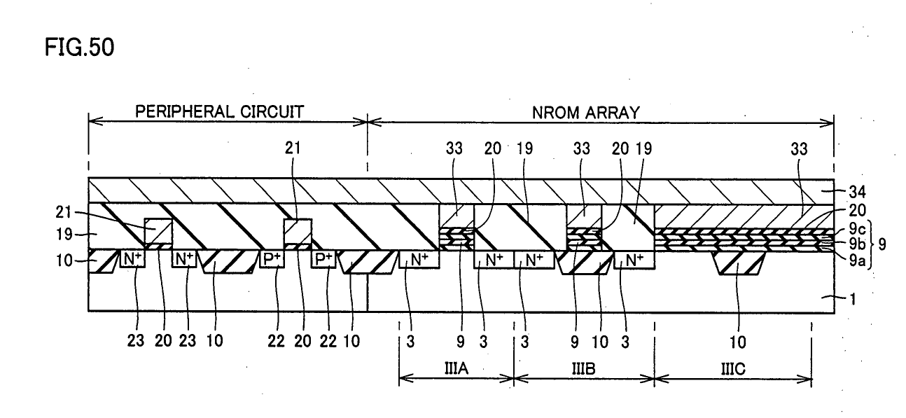

Next, as shown in FIG. 50, a polysilicon film 34 into which impurities are doped is deposited over the entirety of the surface of semiconductor substrate 1 by means of a CVD method or the like. This polysilicon film 34 becomes an upper layer gate portion of transfer gate electrode 11.

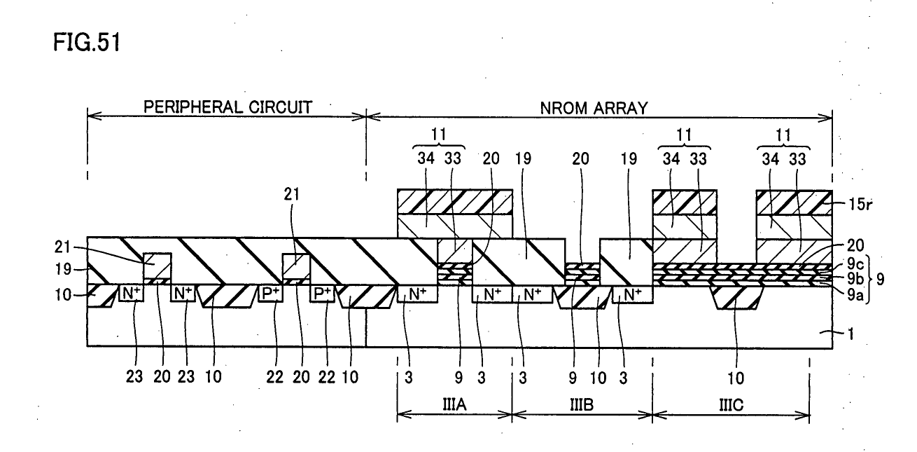

A resist 15r is formed on polysilicon film 34 so as to cover a region wherein transfer gate electrode 11 of memory cell 2 is formed. Polysilicon films 33 and 34 are etched by using this resist 15r as a mask. Thereby, as shown in FIG. 51, transfer gate electrode 11 is formed.

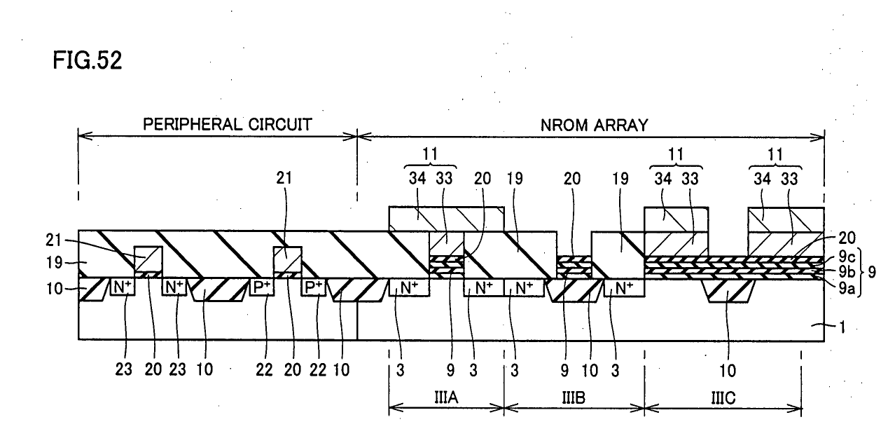

After that, resist 15r is removed so as to gain the structure shown in FIG. 52. Hereinafter, the same process as in the first embodiment is carried out so that the NROM shown in FIG. 36 is formed according to the present third embodiment.

(Fourth Embodiment)

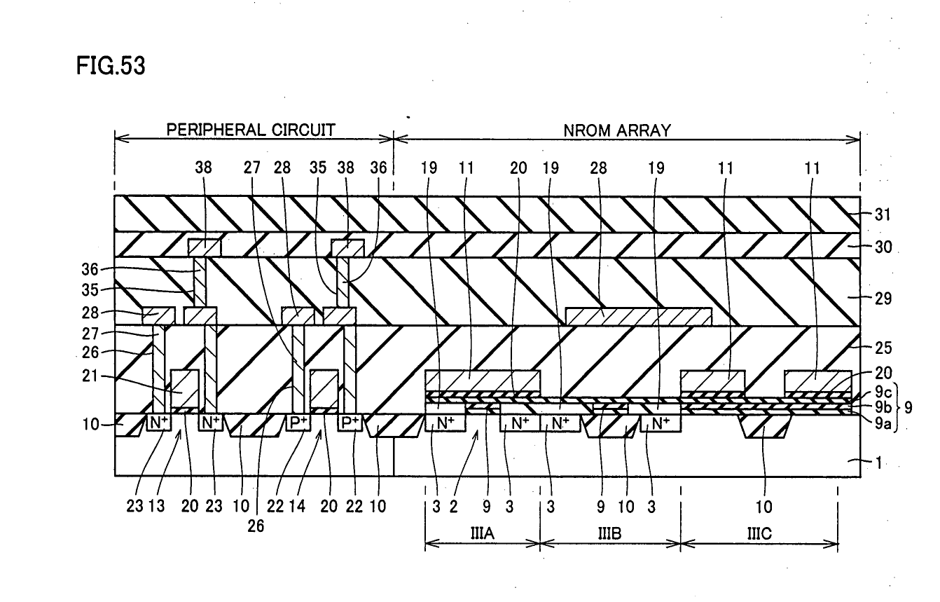

Next, the fourth embodiment of the present invention is described in reference to FIGS. 53 to 64. FIG. 53 is a cross sectional view of an NROM according to the present fourth embodiment.

As shown in FIG. 53, the thickness of gate electrodes 11 of an NMOS transistor 13 and a PMOS transistor 14 and the thickness of a transfer gate electrode 11 are smaller than the thicknesses of those according to the first embodiment. In addition, the thickness of oxide film 19 is approximately the same as the combined thickness of a lower oxide film 9a and a nitride film 9b of an ONO film 9. The structures of the other parts are substantially the same as in the case of the first embodiment, of which the descriptions are omitted.

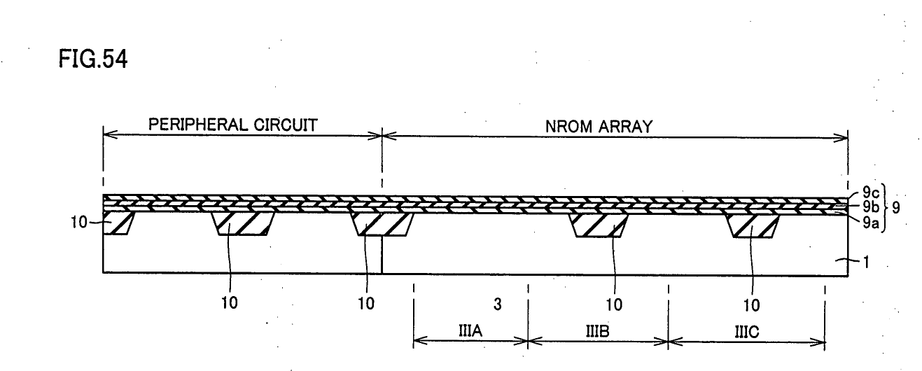

Next, a manufacturing method for an NROM according to the present fourth embodiment is described in reference to FIGS. 54 to 64.

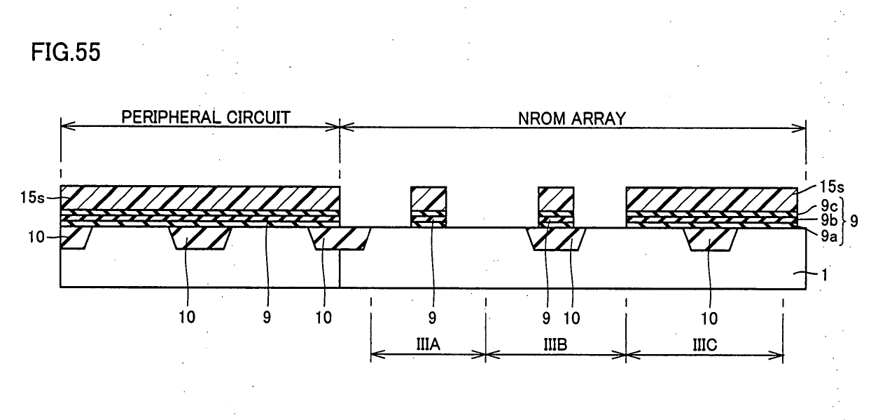

As shown in FIG. 54, trench isolation regions 10 are formed in the main surface of the semiconductor substrate 1 by means of the same technique as in the first embodiment and an ONO film 9 is formed on this main surface. A resist is applied to this ONO film 9 and then, as shown in FIG. 55, a resist 15s having openings above regions wherein a source and a drain of a memory cell 2 are formed is formed by means of a photomechanical process.

ONO film 9 is etched by using this resist 15s as a mask, and thereby, as shown in FIG. 55, the main surface of semiconductor substrate 1 is exposed in the regions wherein the source and the drain gate oxide film memory cell 2 are formed.

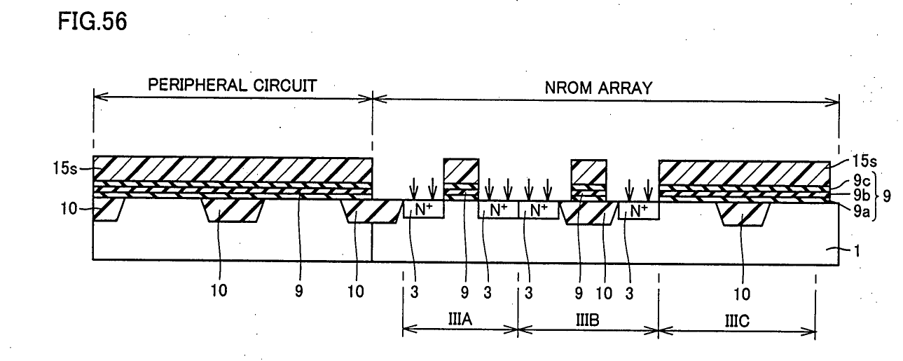

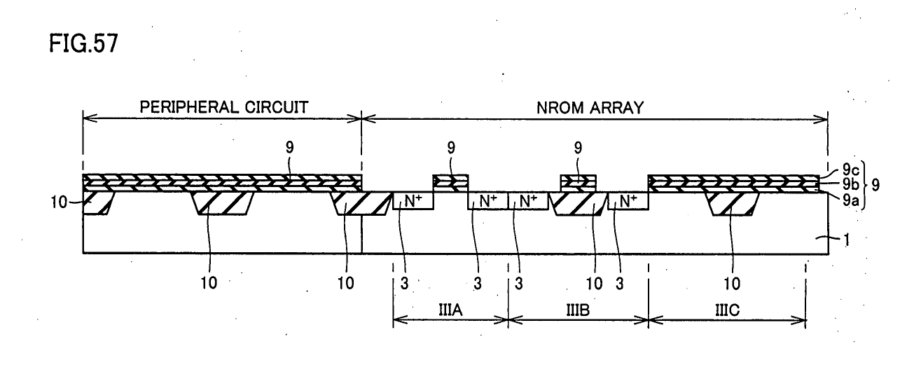

Next, N-type impurities are implanted into semiconductor substrate 1 by using resist 15s and ONO film 9 as a mask. Thereby, as shown in FIG. 56, buried diffusion bit lines 3 are formed. After that, as shown in FIG. 57, resist 15s is removed.

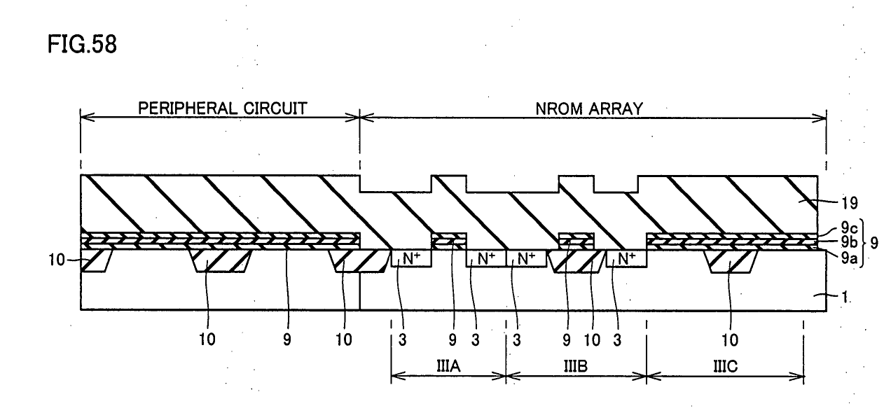

Next, as shown in FIG. 58, an oxide film 19 is deposited on the main surface of semiconductor substrate 1 by means of a CVD method or the like. A thickness reduction process, starting from the upper surface of this oxide film 19, is carried out on this oxide film 19 by means of the same technique as in the first embodiment.

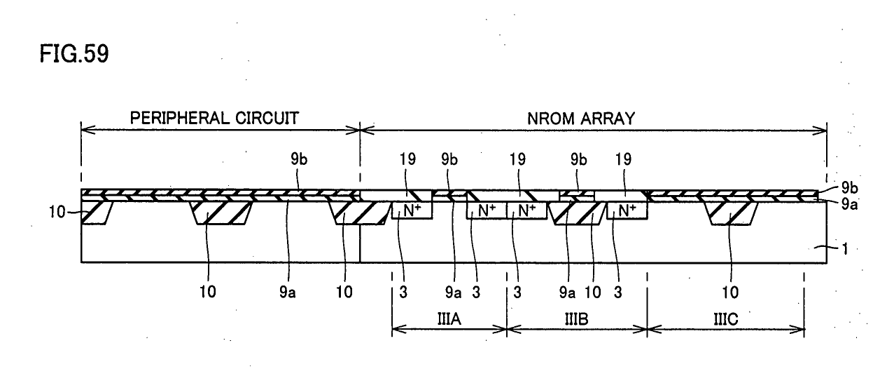

The thickness reduction process such as CMP, etching back or the like can be stopped at nitride film 9b in ONO film 9 made of a material that is different from that of oxide film 19 in the present fourth embodiment. Thereby, as shown in FIG. 59, nitride film 9b is exposed and oxide films 19 can be formed on buried diffusion bit lines 3.

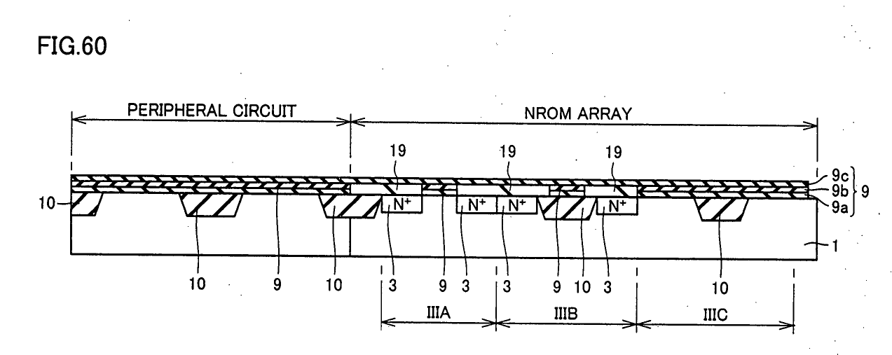

Next, as shown in FIG. 60, an oxide film 9c is formed by means of a CVD method or the like. Thereby, an upper layer oxide film 9c of ONO film 9 can be again formed so as to gain a new interface between upper layer oxide film 9c and nitride film 9b. Accordingly, stress (from heat, gas, and the like) can be prevented during processes such as implantation for a source and a drain of memory cell 2, oxide film deposition, and the like, and, therefore, a clean and stable interface can be formed between upper layer oxide film 9c and nitride film 9b.

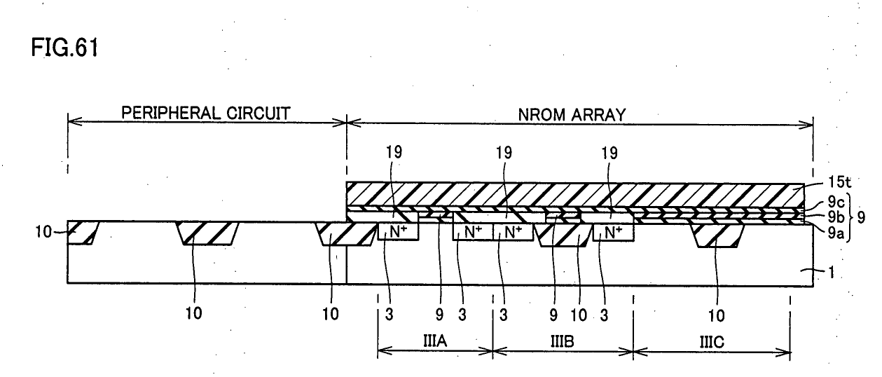

Next, in order to remove ONO film 9 in the peripheral circuit region, a resist is applied to ONO film 9 and then, as shown in FIG. 61, a resist 15t having an opening above the peripheral circuit region is formed by means of a photomechanical process. ONO film 9 above the peripheral circuit region is removed by using this resist 15t as a mask. After that, resist 15t is removed.

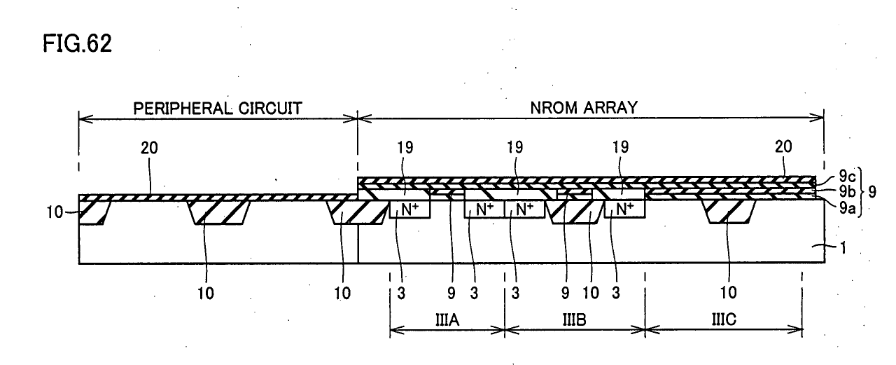

Next, as shown in FIG. 62, an oxide film 20 is formed by means of a thermal oxidation method, a CVD method or the like. This oxide film 20 becomes gate insulating films of NMOS transistor 13 and PMOS transistor 14 in the peripheral circuit region.

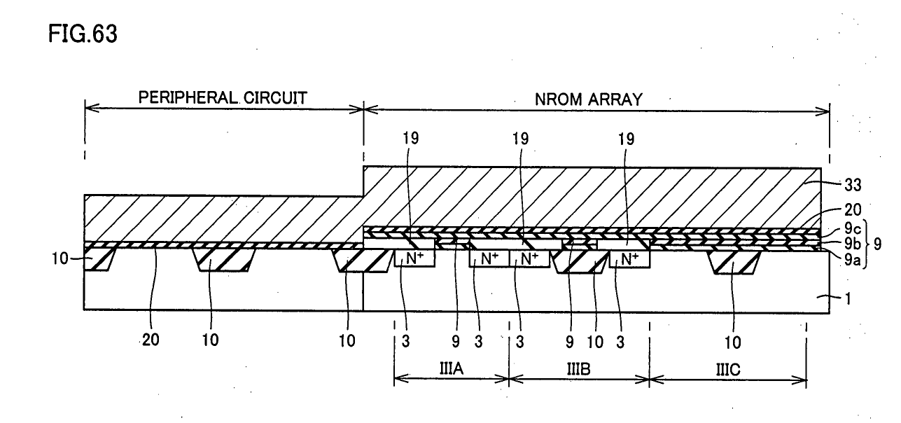

A polysilicon film 33 is formed on oxide film 20 by means of a CVD method or the like, as shown in FIG. 63. CMP or the like, is carried out on this polysilicon film 33 so as to flatten the upper surface of polysilicon film 33. Hereinafter, the same process (process in FIG. 20 and after) in the first embodiment is carried out so that the NROM shown in FIG. 53 is formed.

According to the present invention, the second and third insulating films can be prevented from extending to under the first insulating film and pushing up the edge portions of the first insulating film and, therefore, portions that would become unnecessary portions in the memory cell can be eliminated. Thereby, it becomes easy to scale down the size of the memory cell.

In addition, the first insulating film can be prevented from extending over the second or third insulating film, and thereby the occurrence of extra capacitance and malfunction of the memory cell caused by electrons trapped in the first insulating film that has extended over the second or third insulating film can be avoided. Thereby, the reliability of the non-volatile semiconductor memory device can be improved.

Furthermore, the formation of the second and third insulating films can prevent the occurrence of dispersion in the width of the edge portions of the first and second impurity diffusion regions and, therefore, the operational characteristics of the memory cell can be prevented from being reduced is contrast to the prior art and, as a result, the performance of the non-volatile semiconductor memory device can also be improved.

The above described first insulating film typically has a lamination structure of a first oxide film, a nitride film and a second oxide film. In this case, the nitride film becomes a charge storage part. Then, it is preferable for the first insulating film to be formed between the second and third insulating films without extending over the second and third insulating films. Thereby, problems such as the occurrence of extra capacitance or malfunction of the memory cell due to the first insulating film extending over the second and third insulating films can be solved.

It is preferable for the second and third insulating films to have a thickness substantially uniform in the direction parallel to the main surface and to have flat upper surfaces. The gate electrode extends over the upper surfaces of these second and third insulating films.

The second and third insulating films have a thickness substantially uniform in the direction parallel to the main surface, and thereby the gate electrode and the first and second impurity diffusion regions can be electrically isolated while reducing the maximum thickness of the second and third insulating films. In addition, the second and third insulating films have flat upper surfaces, and thereby the base of the gate electrode can be flattened so that formation of the gate electrode becomes easy.

In a manufacturing method for a non-volatile semiconductor memory device of the present invention, the mask film is preferably formed of, at least, one type of film selected from a group consisting of a film of an organic material, a film of a metal material and a semiconductor film and the second insulating film includes an oxide film. This mask film may be formed of a single film or may be formed of a plurality of films.

The mask film can be allowed to function as a stopper at the time of the thickness reduction process of the second insulating film by selecting the above described material as the material for the mask film. Thereby, the second insulating film can be allowed to remain between the patterned first insulating films.

In addition, the first insulating film typically has a lamination structure of a first oxide film, a nitride film and a second oxide film and the mask film includes the above described polysilicon film. In this case it is preferable to carry out a heat treatment on the first insulating film after the formation of the mask film. The quality of the first insulating film can be improved by carrying out such a heat treatment.

The non-volatile semiconductor memory device has a memory cell region wherein memory cells are formed and a peripheral circuit region wherein a peripheral circuit for carrying out operational control of memory cells is formed. In addition, the first insulating film has a lamination structure of a first oxide film, a nitride film and a second oxide film and the mask film includes a polysilicon film. In this case, the process of formation of the mask film includes the step of patterning the first insulating film so as to expose the main surface of the semiconductor substrate in the peripheral circuit region, the step of forming a polysilicon film above the exposed main surface and above the first insulating film via the third insulating film and the step of patterning the polysilicon film and the third insulating film so as to form the mask film and so as to form gate electrodes of MOS (Metal Oxide Semiconductor) transistors in the peripheral circuit region.

Thus, the third insulating film and the polysilicon film are formed after removing the first insulating film in the peripheral circuit region, and thereby this laminated film can be utilized as a mask film in the memory cell region and can be utilized as gate insulating films and gate electrodes MOS transistors in the peripheral circuit region.

In a manufacturing method for a non-volatile semiconductor memory device according to another aspect of the present invention, it is preferable to form an oxide film on a nitride film after the exposure of the nitride film. Thereby, the upper layer oxide film in the first insulating film can be formed in the subsequent process and a new interface between the nitride film and the upper layer oxide film can be formed. As a result, an interface wherein the influence of process stress is low is gained so that the quality of the first insulating film can be improved.

In addition, the second insulating film preferably includes an oxide film. Thereby, at the time when the thickness reduction process is carried out on the second insulating film, starting from upper surface of the second insulating film, this process can be stopped at the nitride film of the first insulating film.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A non-volatile semiconductor memory device comprising:
a semiconductor substrate having a main surface;
a first insulating film formed on said main surface and having a charge storage part;
first and second impurity diffusion regions formed in said semiconductor substrate located on both sides of said first insulating film;
second and third insulating films deposited on said main surface so as to cover said first and second impurity diffusion regions; and
a gate electrode formed on said first insulating film.

2. The non-volatile semiconductor memory device according to claim 1, wherein
said first insulating film has a lamination structure of a first oxide film, a nitride film and a second oxide film,
said nitride film serves as said charge storage part, and
said first insulating film is formed between said second and third insulating films without extending over said second and third insulating films.

3. The non-volatile semiconductor memory device according to claim 1, wherein
said second and third insulating films have a thickness which is substantially uniform in a direction parallel to said main surface, and have a flat upper surface, and
said gate electrode extends over the upper surfaces of said second and third insulating films.

4. A manufacturing method for a non-volatile semiconductor memory device, comprising the steps of:
forming a first insulating film having a charge storage part on a main surface of a semiconductor substrate;
selectively forming a mask film on said first insulating film, and patterning said first insulating film by using the mask film;
implanting impurities into said semiconductor substrate by using said mask film and said patterned first insulating film as a mask, and forming first and second impurity diffusion regions;
depositing a second insulating film over said main surface so as to cover said mask film and first and second impurity diffusion regions;
reducing the thickness of said second insulating film from the upper surface of said second insulating film, and exposing said mask film and filling in said second insulating film between said patterned first insulating films; and
forming a gate electrode on said first insulating film after removing said mask film.

5. The manufacturing method for a non-volatile semiconductor memory device according to claim 4, wherein
said mask film is formed of at least one type of film selected from a group consisting of a film of an organic material, a film of a metal material and a semiconductor film, and
said second insulating film includes an oxide film.

6. The manufacturing method for a non-volatile semiconductor memory device according to claim 4, wherein
said first insulating film has a lamination structure of a first oxide film, a nitride film and a second oxide film,
said mask film includes a polysilicon film and
a heat treatment is carried out on said first insulating film after the formation of said mask film.

7. The manufacturing method for a non-volatile semiconductor memory device according to claim 4, wherein
said non-volatile semiconductor memory device has a memory cell region in which memory cells are formed and a peripheral circuit region in which a peripheral circuit is formed for carrying out operational control of the memory cells,
said first insulating film has a lamination structure of a first oxide film, a nitride film and a second oxide film,
said mask film includes a polysilicon film, and
the formation process of said mask film includes the steps of:
patterning said first insulating film so as to expose the main surface of said semiconductor substrate in said peripheral circuit region;
forming said polysilicon film above said exposed main surface and said first insulating film via a third insulating film; and
patterning said polysilicon film and said third insulating film so as to form said mask film and form a gate electrode of a MOS (Metal Oxide Semiconductor) transistor in said peripheral circuit region.

8. A manufacturing method for a non-volatile semiconductor memory device, comprising the steps of:
forming a first insulating film having a lamination structure formed of a first oxide film, a nitride film served as a charge storage part, and a second oxide film, on a main surface of a semiconductor substrate;
selectively forming a mask film on said first insulating film, and patterning said first insulating film by using the mask film;
implanting impurities into said semiconductor substrate by using said mask film and said patterned first insulating films as a mask, and thereby forming first and second impurity diffusion regions;
removing said mask film;
depositing a second insulating film over said main surface so as to cover said first and second impurity diffusion regions;
reducing the thickness of said second insulating film from the upper surface of said second insulating film, and thereby exposing said nitride film and filling in said second insulating film between said patterned first insulating films; and
forming a gate electrode on said first insulating film.

9. The manufacturing method for a non-volatile semiconductor memory device according to claim 8, comprising a step of forming an oxide film on said nitride film after the exposure of said nitride film.

10. The manufacturing method for a non-volatile semiconductor memory device according to claim 8, wherein said second insulating film includes an oxide film.
